(19) United States
(12) Patent Application Publication
(10) Pub. No.: US 2026/0344008 A1
(43) Pub. Date: Oct. 29, 2026

(54) FORMING CFETS THROUGH LOW-TEMPERATURE RE-GROWTH

(71) Applicant: Taiwan Semiconductor Manufacturing Co., Ltd., Hsinchu (TW)

(72) Inventors: Che Chi Shih, Taoyuan City (TW); Cheng-Wei Liu, Hsinchu (TW); Wei-De Ho, Hsinchu (TW); Ji-Yin Tsai, Zhudong Township (TW); Ku-Feng Yang, Baoshan Township (TW); Pei-Ren Jeng, Chu-Bei City (TW); Szuya Liao, Zhubei (TW)

(21) Appl. No.: 19/732,769

(22) Filed: Jul. 7, 2026

Related U.S. Application Data
(63) Continuation of application No. 19/087,847, filed on Mar. 24, 2025.
(60) Provisional application No. 63/718,011, filed on Nov. 8, 2024.

(51) Int. Cl. H10D 84/01; H10D 84/85

(52) U.S. Cl. CPC H10D 84/017; H10D 84/0186; H10D 84/851; H10D 84/856

(57) ABSTRACT

A method includes forming a lower transistor and an upper transistor over the lower transistor. The lower transistor comprises a lower source/drain region over a semiconductor substrate, and the lower source/drain region comprises a bottom side facing the semiconductor substrate. The upper transistor comprises an upper source/drain region over the lower source/drain region. The method further comprises forming a contact opening to expose the bottom side of the lower source/drain region, performing an epitaxy process to grow a semiconductor layer on the lower source/drain region, and forming a silicide layer electrically connected to the lower source/drain region through the semiconductor layer. By re-growing low-temperature epitaxy semiconductor layers from the backside of source/drain regions, the resistance of the lower source/drain regions and the respective contact resistance are reduced. By adopting low-temperature epitaxy to form source/drain regions, the resistance of the source/drain regions and the respective contact plugs are reduced.

### PRIORITY CLAIM AND CROSS-REFERENCE

This application is a continuation of U.S. patent application Ser. No. 19/087,847 filed on Mar. 24, 2025, which application claims the benefit of the following provisionally filed U.S. Patent Application No. 63/718,011, filed on Nov. 8, 2024, which applications are hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of example Complementary Field-Effect Transistors (CFETs) in accordance with some embodiments.

FIGS. 2-6, 7A, 7B and 8-16 are views of intermediate stages in the fabrication of CFETs in accordance with some embodiments.

FIG. 17 illustrates a process flow for fabricating the CFETs in FIG. 16 in accordance with some embodiments.

FIGS. 18-37 are views of intermediate stages in the fabrication of CFETs in accordance with some embodiments.

FIG. 38 illustrates a process flow for fabricating the CFETs in FIG. 37 in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Complementary Field-Effect Transistors (CFETs) and the methods of forming the same are provided. In accordance with some embodiments, each CFET includes a lower source/drain region and an upper source/drain region overlapping the lower source/drain region. A backside regrow process is performed from the backside of the CFETs. Germanium-comprising epitaxy layers are formed from the backside of the lower source/drain region. The epitaxy process may be performed at low temperature to achieve a high activation rate in the lower source/drain region.

In accordance with the alternative embodiments, dummy lower source/drain regions and dummy upper source/drain regions are formed. The dummy upper source/drain regions are then removed from the front side of the respective wafer, and replacement upper source/drain regions are formed through low-temperature epitaxy. The dummy lower source/drain regions are removed from the backside of the respective wafer, and replacement lower source/drain regions are formed through low-temperature epitaxy. The dummy source/drain regions facilitate the self-alignment of the low-temperature epitaxy. The low-temperature epitaxy improves the activation of the replacement source/drain regions.

It is appreciated that while Gate-All-Around (GAA) transistors (such as nanostructure-FETs) are discussed as examples, the concept of the present disclosure can also be applied to the formation of other types of transistors such as planar transistors, Fin Field-Effect Transistors (FinFETs), or the like. Throughout the description, the terms “FET” and “transistor” are used interchangeably.

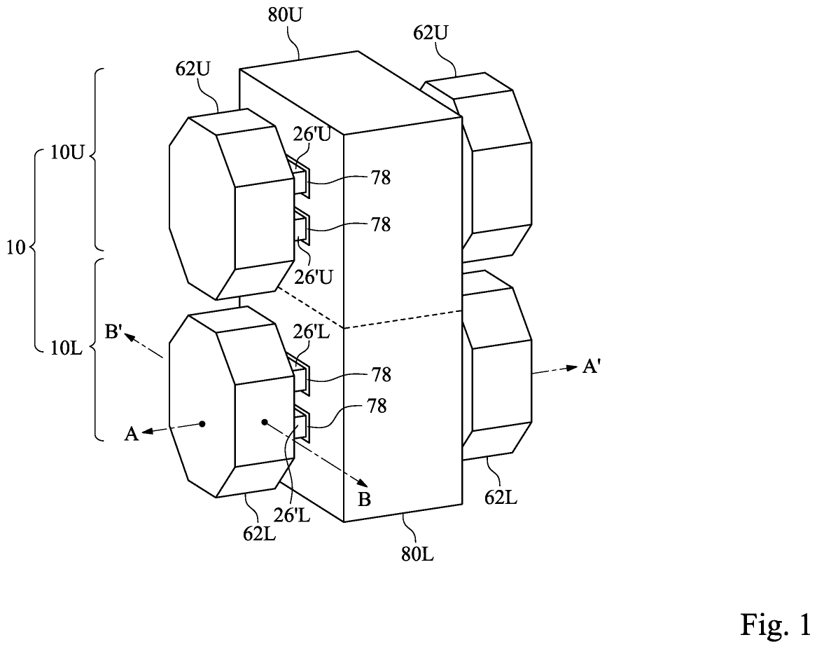

FIG. 1 illustrates an example of CFETs 10 (including FETs (transistors) 10U and 10L) in accordance with some embodiments. FIG. 1 is a three-dimensional view, wherein some features of the CFETs are omitted for illustration clarity.

The CFETs include multiple vertically stacked FETs. For example, a CFET may include a lower nanostructure-FET 10L of a first device type (e.g., n-type/p-type) and an upper nanostructure-FET 10U of a second device type (e.g., p-type/n-type) that is opposite the first device type. The nanostructure-FETs 10U and 10L include semiconductor nanostructures 26′ (including lower semiconductor nanostructures 26'L and upper semiconductor nanostructures 26′U), where the semiconductor nanostructures 26′ act as the channel regions for the nanostructure-FETs. The lower semiconductor nanostructures 26′L are for the lower nanostructure-FET 10L, and the upper semiconductor nanostructures 26′U are for the upper nanostructure-FET 10U.

Gate dielectrics 78 encircle the respective semiconductor nanostructures 26′. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. The source/drain region may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A′ is a vertical cross-section that is parallel to a longitudinal axis of the semiconductor nanostructures 26′ of a CFET and in a direction of, for example, a current flow between the source/drain regions 62 of the CFET. Cross-section B-B′ is a vertical cross-section that is perpendicular to cross-section A-A′ and along a longitudinal axis of a gate electrode 80 of the CFET. Subsequent figures may refer to these reference cross-sections for clarity.

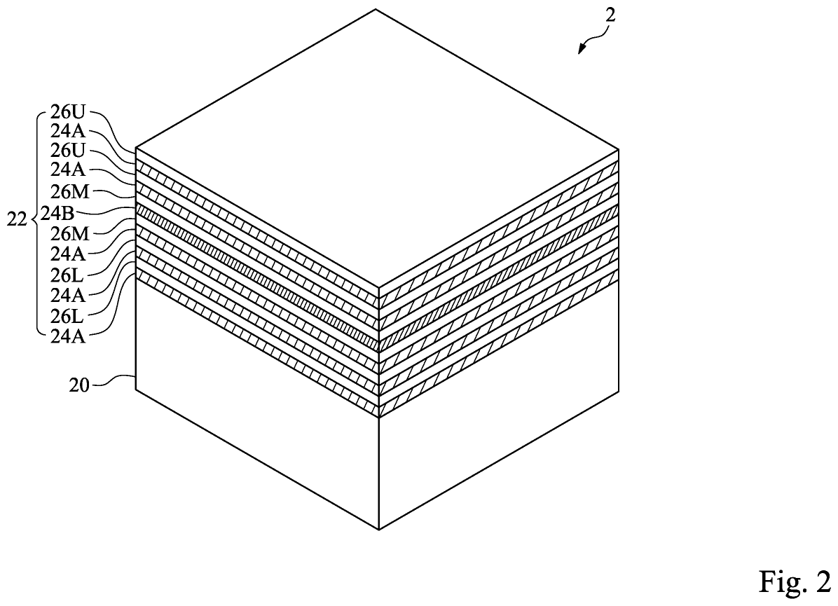

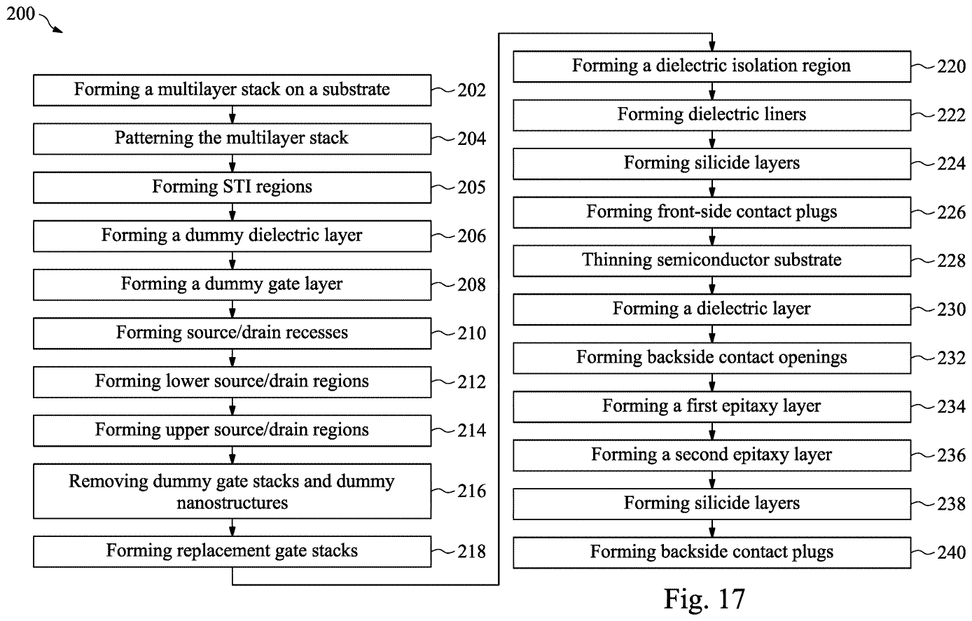

FIGS. 2 through 17 illustrate the cross-sectional views of intermediate stages in the formation of CFETs (as schematically represented in FIG. 1) in accordance with some embodiments. The corresponding processes are also reflected schematically in the process flow 200 as shown in FIG. 17. In subsequent discussion, unless specified otherwise, the figures having digits followed by letter “A” illustrate the vertical cross-sectional views along a similar cross-section as vertical reference cross-section A-A′ in FIG. 1. The figures having digits followed by letter “B” illustrate the cross-sectional views along a similar cross-section as the vertical reference cross-section B-B′ in FIG. 1.

In FIG. 2, wafer 2, which includes substrate 20, is provided. Substrate 20 may be a semiconductor substrate, such as a bulk semiconductor, a semiconductor-on-insulator (SOI) substrate, or the like, which may be doped (e.g., with a p-type or an n-type dopant) or undoped. The SOI substrate may include a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multilayered or gradient substrate may also be used. In some embodiments, the semiconductor material of the substrate 20 may include silicon, germanium, carbon-doped silicon, a III-V compound semiconductor; or the like, or combinations thereof.

A multilayer stack 22 is formed over the substrate 20. The respective process is illustrated as process 202 in the process flow 200 as shown in FIG. 17. The multilayer stack 22 includes alternating dummy semiconductor layers 24 (including dummy semiconductor layers 24A and 24B) and semiconductor layers 26 (including lower semiconductor layers 26L, middle semiconductor layers 26M, and upper semiconductor layers 26U). Lower semiconductor layers 26L and upper semiconductor layers 26U are for forming a lower FET and an upper FET, respectively.

Appropriate wells (not separately illustrated) may be formed in lower semiconductor layers 26L and upper semiconductor layers 26U. For example, semiconductor layers 26L and 26U may be in-situ doped (when epitaxially grown) and/or implanted to desirable conductivity types.

In the illustrated example, the multilayer stack 22 includes six of the dummy semiconductor layers 24 and six of the semiconductor layers 26. It should be appreciated that the multilayer stack 22 may include any number of the dummy semiconductor layers 24 and the semiconductor layers 26. Each layer of the multilayer stack 22 may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like.

The dummy semiconductor layers 24A are formed of a first semiconductor material, the dummy semiconductor layer 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy semiconductor layer 24B may be removed at a faster rate than the dummy semiconductor layers 24A in subsequent processes.

The semiconductor layers 26 (including the lower semiconductor layers 26L and upper semiconductor layers 26U) are formed of one or more semiconductor material(s). The semiconductor material(s) may be selected from the candidate semiconductor materials of the substrate 20. The lower semiconductor layers 26L and the upper semiconductor layers 26U may be formed of the same semiconductor material, or may be formed of different semiconductor materials.

In some embodiments, dummy semiconductor layers 24A are formed of or comprise silicon germanium, semiconductor layers 26 are formed of silicon, and dummy semiconductor layer 24B may be formed of germanium or silicon germanium that has a higher germanium atomic percentage than in semiconductor layer 24A.

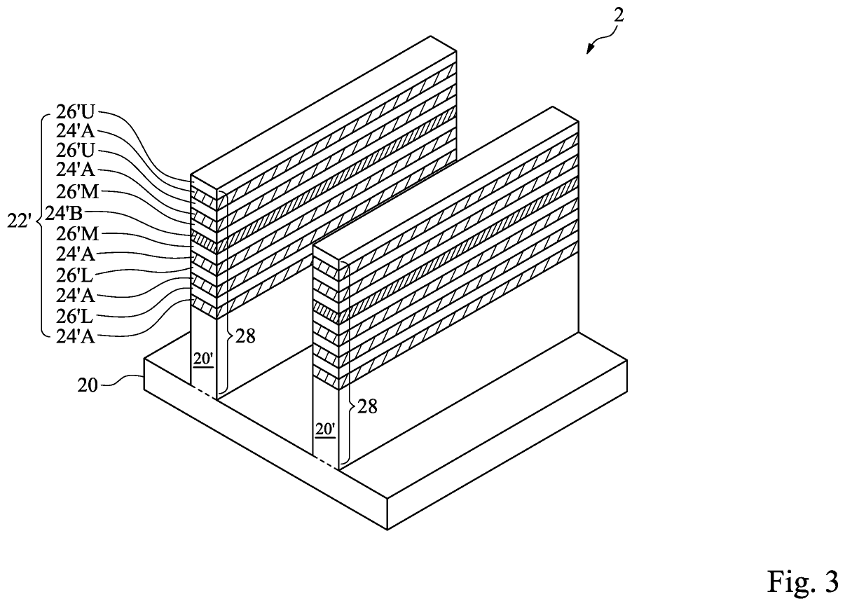

In FIG. 3, multilayer stack 22 and substrate 20 are patterned to form semiconductor strips 28. The respective process is illustrated as process 204 in the process flow 200 as shown in FIG. 17. Each of semiconductor strips 28 includes semiconductor strip 20′ (the portions of the original substrate 20) and multilayer stack 22′, which is the remaining portion of multilayer stack 22. The remaining portions 22′ of multilayers stack 22 are referred to as nanostructures hereinafter, which are referred to using the corresponding reference number followed by a “ ” sign. Accordingly, multilayer stack 22′ includes dummy nanostructures 24′A, dummy nanostructures 24′B, lower semiconductor nanostructures 26′L, middle semiconductor nanostructures 26′M, and upper semiconductor nanostructures 26′U. The etching may be performed by any acceptable etch process, such as a Reactive Ion Etch (RIE), Neutral Beam Etch (NBE), the like, or a combination thereof. The etching may be anisotropic. Dummy nanostructures 24′A and dummy nanostructures 24′B may further be collectively referred to as dummy nanostructures 24′. The lower semiconductor nanostructures 26′L and the upper semiconductor nanostructures 26′U may further be collectively referred to as semiconductor nanostructures 26′.

The lower semiconductor nanostructures 26′L will act as channel regions for lower nanostructure-FETs of the CFETs. The upper semiconductor nanostructures 26′U will act as channel regions for upper nanostructure-FETs of the CFETs. The middle semiconductor nanostructures 26′M are the semiconductor nanostructures 26′ that are immediately above/below (e.g., in contact with) the dummy nanostructures 24′B. The middle semiconductor nanostructures 26′M may be used for isolation and may or may not act as channel regions for the CFETs. The dummy nanostructures 24′B will be subsequently replaced with isolation structures. The isolation structures and the middle semiconductor nanostructures 26′M may define boundaries of the lower nanostructure-FETs and the upper nanostructure-FETs.

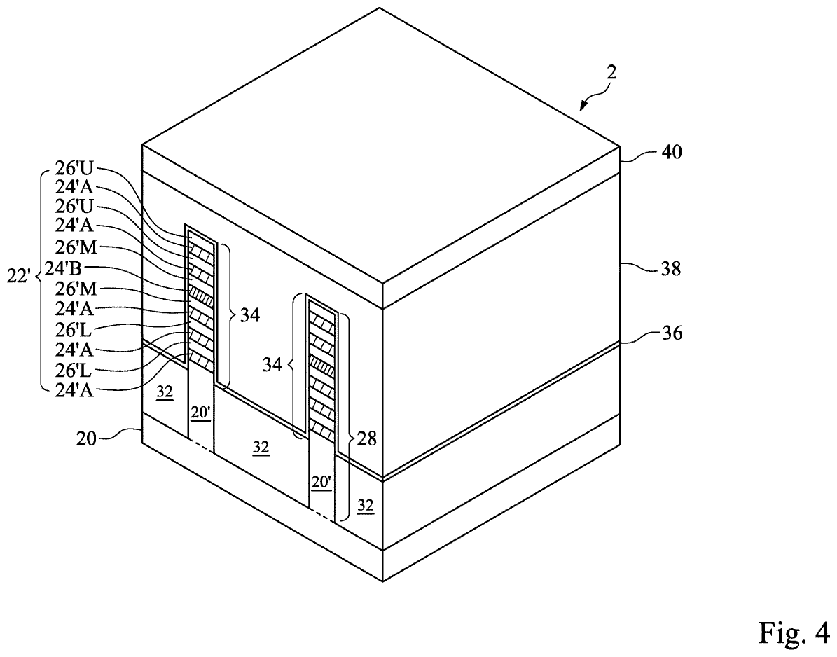

In FIG. 4, isolation regions 32 are formed over the substrate 20 and between adjacent semiconductor strips 28. The respective process is illustrated as process 205 in the process flow 200 as shown in FIG. 17. Isolation regions 32 may include a dielectric liner and a dielectric material over the dielectric liner. Isolation regions 32 are then recessed. Some upper portions of semiconductor strips 28 (including multilayer stacks 22′) protrude higher than the remaining isolation regions 32 to form protruding fins 34.

Dummy dielectric layer 36 is then formed on the protruding fins 34. The respective process is illustrated as process 206 in the process flow 200 as shown in FIG. 17. Dummy dielectric layer 36 may be formed of or comprise, for example, silicon oxide, silicon nitride, a combination thereof, or the like, and may be deposited or thermally grown according to acceptable techniques.

A dummy gate layer 38 is formed over the dummy dielectric layer 36. The respective process is illustrated as process 208 in the process flow 200 as shown in FIG. 17. The dummy gate layer 38 may be deposited, for example, through Physical Vapor Deposition (PVD), CVD, or other techniques, and then planarized, such as by a CMP process. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like.

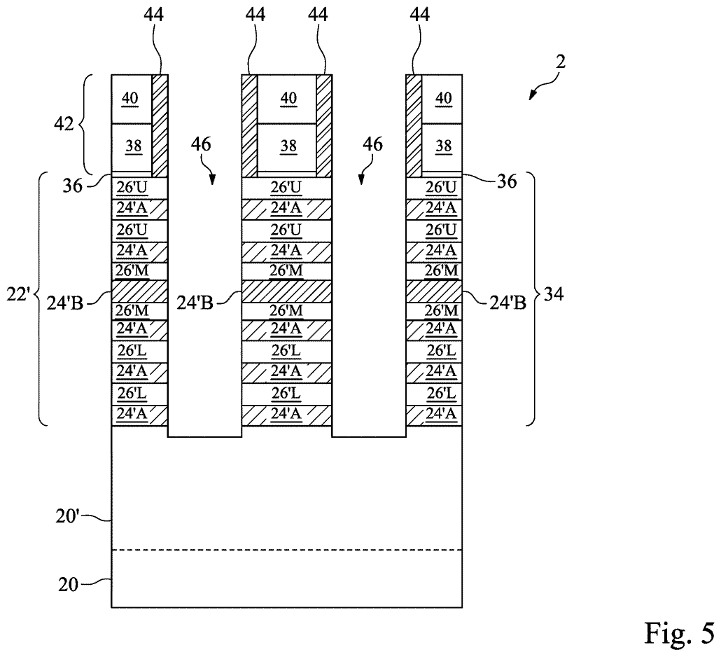

Next, the mask layer 40 may be patterned through photolithography and etching processes to form a mask, which is then used to etch and pattern dummy gate layer 38, and possibly dummy dielectric layer 36. A resulting structure is shown in FIG. 5. The remaining portions of mask layer 40, dummy gate layer 38, and dummy dielectric layer 36 form dummy gate stacks 42.

In FIG. 5, gate spacers 44 are formed over the multilayer stacks 22′ and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxy-carbo-nitride, or the like, which may be formed by a deposition process such as CVD, ALD, or the like.

Source/drain recesses 46 are then formed in semiconductor strips 28. The respective process is illustrated as process 210 in the process flow 200 as shown in FIG. 17. The source/drain recesses 46 are formed through etching, and may extend through the multilayer stacks 22′ and into the semiconductor strips 20′. The bottom surfaces of the source/drain recesses 46 may be at a level above, below, or level with the top surfaces of the isolation regions 32 (FIG. 4). In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon source/drain recesses 46 reaching a desired depth.

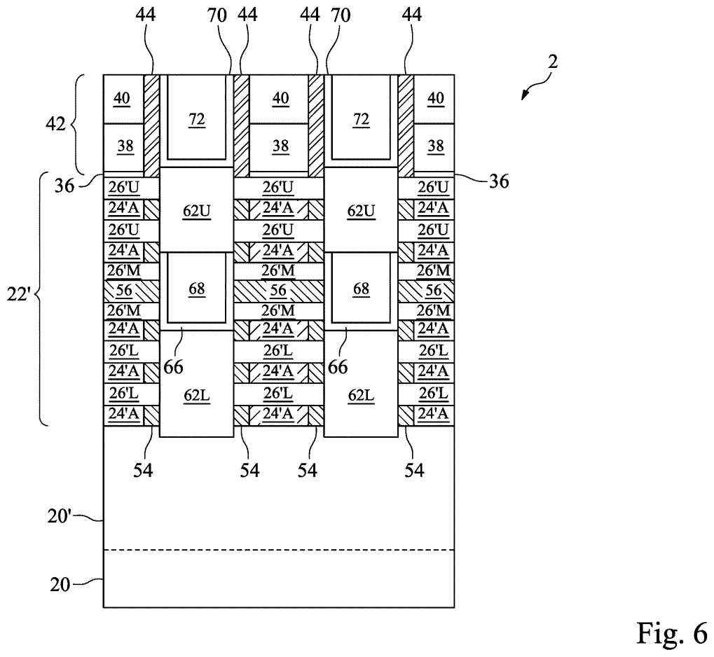

Dummy nanostructures 24′A are then laterally recessed, and a dielectric material is filled into the respective recesses to form inner spacers 54, which are dielectric spacers. The resulting structure is shown in FIG. 6. Dielectric isolation layers 56 are also formed to replace the dummy nanostructures 24′B.

Next, lower epitaxial source/drain regions 62L are formed in the lower portions of the source/drain recesses 46 (FIG. 5). The respective process is illustrated as process 212 in the process flow 200 as shown in FIG. 17. The lower epitaxial source/drain regions 62L are in contact with the lower semiconductor nanostructures 26′L and are not in contact with the upper semiconductor nanostructures 26′U. Inner spacers 54 electrically insulate the lower epitaxial source/drain regions 62L from the dummy nanostructures 24′A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants.

In accordance with some embodiments, the temperature for forming the lower epitaxial source/drain regions 62L may be a relatively high temperature, which may be in the range between about 550 °C and about 800 °C.

A first contact etch stop layer (CESL) 66 and a first ILD 68 are formed. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26′U are exposed.

Next, upper epitaxial source/drain regions 62U are formed in the upper portions of the source/drain recesses 46. The respective process is illustrated as process 214 in the process flow 200 as shown in FIG. 17. The materials of upper epitaxial source/drain regions 62U may be selected from the same candidate group of materials for forming lower source/drain regions 62L, depending on the desired conductivity type of upper epitaxial source/drain regions 62U.

The conductivity type of the upper epitaxial source/drain regions 62U may be opposite the conductivity type of the lower epitaxial source/drain regions 62L. Alternatively stated, the upper epitaxial source/drain regions 62U may be oppositely doped from the lower epitaxial source/drain regions 62L. The upper epitaxial source/drain regions 62U may be in-situ doped, and/or may be implanted, with an n-type or p-type dopant.

Next, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the dummy gate stacks 42 are coplanar (within process variations). The planarization process may remove masks 40, or leave hard masks 40 unremoved.

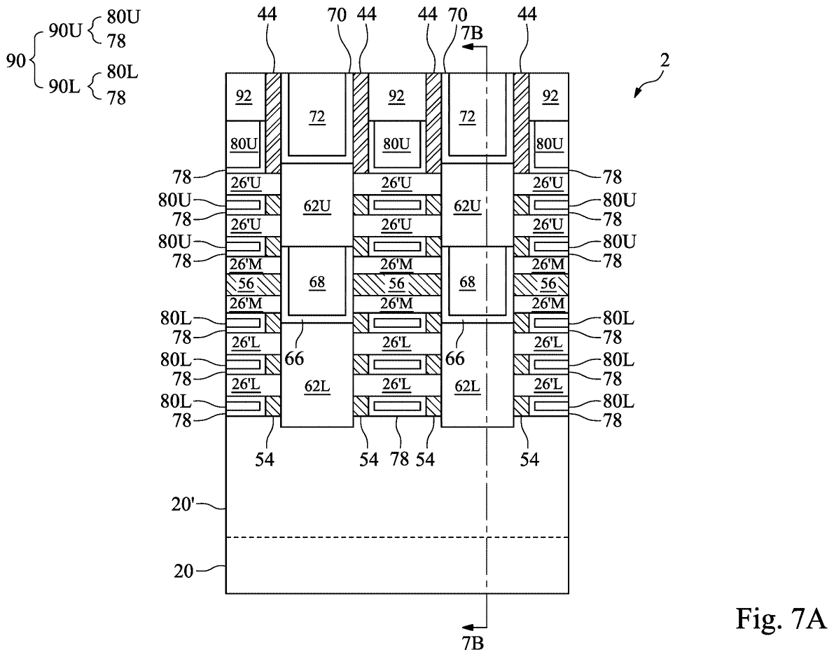

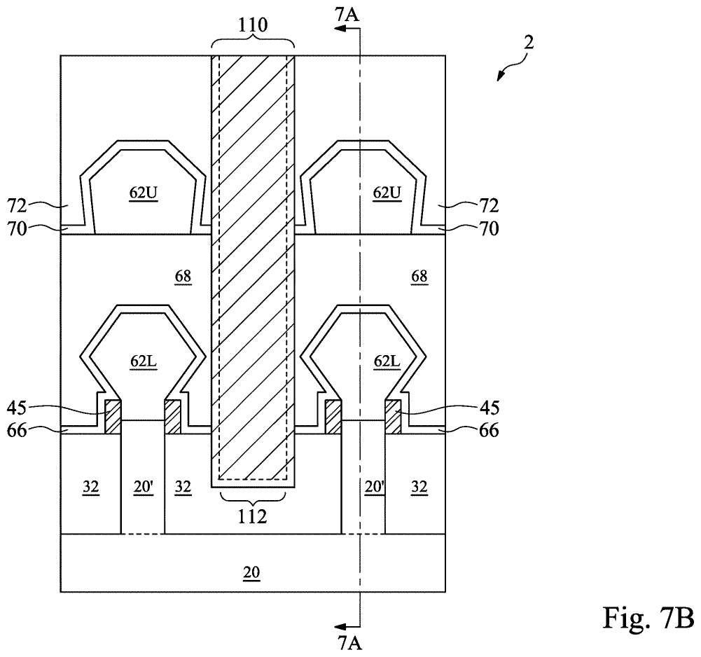

The dummy gate stacks 42 are then removed in one or more etching processes, so that recesses (FIG. 7A, occupied by gate stacks 90 and dielectric hard masks 92) are formed. Each of the recesses exposes and/or overlies portions of multilayer stacks 22′. The respective process is illustrated as process 216 in the process flow 200 as shown in FIG. 17.

The remaining portions of the dummy nanostructures 24′A (FIG. 6) are then removed through etching, so that the recesses extend between the semiconductor nanostructures 26′. The respective process is also illustrated as process 216 in the process flow 200 as shown in FIG. 17. In the etching process, the dummy nanostructures 24′A are etched at a faster rate than the semiconductor nanostructures 26′, the dielectric isolation layers 56, and the inner spacers 54. The etching may be isotropic. For example, when the dummy nanostructures 24′A are formed of silicon-germanium, and the semiconductor nanostructures 26′ are formed of silicon, the etch process may include a wet etch process using tetramethylammonium hydroxide (TMAH), ammonium hydroxide (NH₄OH), or the like.

Replacement gate stacks 90 (including gate stacks 90L and 90U) are formed in the respective recesses, as shown in FIG. 7A. The respective process is illustrated as process 218 in the process flow 200 as shown in FIG. 17. The resulting gate stacks 90L include gate dielectrics 78 and gate electrodes 80L. The resulting gate stacks 90U include gate dielectrics 78 and gate electrodes 80U.

The gate dielectrics 78 are formed on the exposed surfaces of the exposed features including the semiconductor nanostructures 26′ and the gate spacers 44. The gate dielectrics 78 wrap around all (e.g., four) sides of the semiconductor nanostructures 26′. Each of the gate dielectrics 78 may include an interfacial layer, which may include an oxide such as silicon oxide. The interfacial layer may be formed through a thermal oxidation process and/or a deposition process. The gate dielectrics 78 may also include high-k dielectric layers, which have a high dielectric constant (high-k) value greater than, for example, about 7.0. High-k dielectric layers may be formed of or comprise a metal oxide or a silicate of a metal selected from hafnium, zirconium, barium, titanium, lead, and combinations thereof.

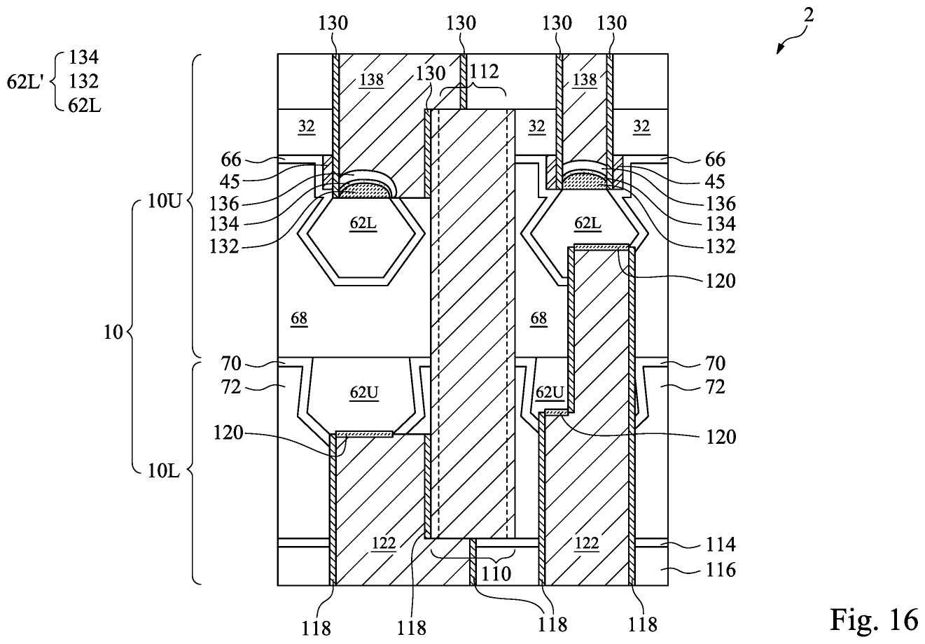

Gate electrodes 80L and 80U are also formed. In the formation process, conductive layers are first formed on the high-k dielectric layer, and the remaining portions of the recesses are filled. Each of gate electrodes 80L and 80U may include a metal-containing material such as TiN, TaN, TiAl, TiAlC, cobalt, ruthenium, aluminum, tungsten, combinations thereof, and/or multilayers thereof. The gate electrodes 80L and 80U may provide work-functions suitable to the resulting lower FETs (lower transistors) 10L (FIG. 16) and upper FETs (upper transistors) 10U (FIG. 16). The gate electrodes 80L and 80U may be common gates formed in a same formation process, or may be electrically disconnected from each other and formed in separate formation processes. Dielectric hard masks 92 are formed over the gate stacks 90U.

FIG. 7B illustrates a cross-sectional view of the structure as shown in FIG. 7A. The illustrated cross-section may be the cross-section 7B-7B as in FIG. 7A. As shown in FIG. 7B, STI regions 32 are formed over substrate 20. Semiconductor strips 20′ are formed between the STI regions 32. Fin spacers 45 may be formed on the sidewalls of the top portions of semiconductor strips 20′. Lower source/drain regions 62L, the first CESL 66, the first ILD 68, the upper source/drain regions 62U, the second CESL 70, and the second ILD 72 are illustrated.

Dielectric isolation region 110 is formed. The respective process is illustrated as process 220 in the process flow 200 as shown in FIG. 17. Dielectric isolation region 110 penetrates through the second ILD 72, the second CESL 70, the first ILD 68, and the first CESL 66. The formation process may include performing an etching process(es) to form a trench, and filling the trench with a dielectric material. Dielectric isolation region 110 may be used as a cut-metal-gate region, which is used to cut long gate stacks into shorter portions, for example, each being used as a gate stack of one of CFETs.

In accordance with some embodiments, the material of dielectric isolation region 110 may include silicon nitride, a metal oxide of a metal such as Hf, Ti, Al, W, Nb, Re, or the like, a metal nitride of a metal such as Hf, Ti, Al, W, Nb, Re, or the like, or combinations thereof.

In accordance with some embodiments, there is no conductive feature formed in dielectric isolation region 110. In accordance with alternative embodiments, dielectric isolation region 110 is formed as a dielectric liner, and a conductive feature 112, which is a conductive plug, is formed inside and encircled by the dielectric isolation region 110. Conductive feature 112 may be used for electrically conducting the features formed on the front side of the CFETs to the backside of the CFETs. Conductive feature 112 is illustrated as being dashed to indicate that it may or may not be formed.

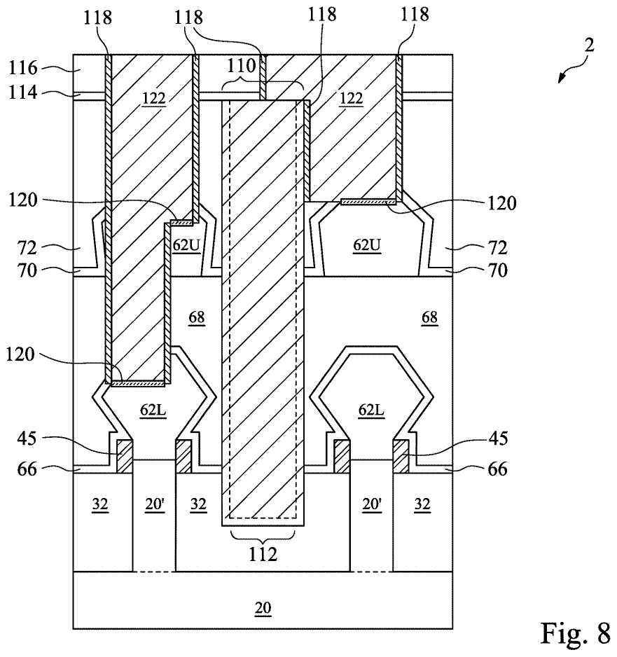

Referring to FIG. 8, etch stop layer 114 and dielectric layer 116 are formed. Etch stop layer 114 may comprise AlN, AlO, SiOC, or the like, or multilayers thereof. Dielectric layer 116 may comprise silicon oxide, silicon nitride, silicon oxynitride, silicon carbide, or the like.

In a subsequent process, dielectric liners 118, silicide layers 120, and contact plugs 122 are formed. In accordance with some embodiments, the formation process includes etching dielectric layer 116, etch stop layer 114, the second ILD 72, the second CESL 70, the first ILD 68, and the first CESL 66 to form contact openings, so that upper source/drain regions 62U are exposed.

Dielectric liners 118 are then formed in the contact openings. The respective process is illustrated as process 222 in the process flow 200 as shown in FIG. 17. The formation process may include depositing a conformal dielectric layer through a conformal deposition process, and preforming an anisotropic etching process to remove the horizontal portions of the conformal dielectric layer. The vertical portions of the conformal dielectric layer are left as being the dielectric liners 118. The material of dielectric liners 118 may comprise silicon nitride, silicon oxynitride, silicon carbo-nitride, or the like.

FIG. 8 further illustrates the formation of silicide layers 120 on the top surfaces of upper source/drain regions 62U. The respective process is illustrated as process 224 in the process flow 200 as shown in FIG. 17. The formation process may include depositing a metal layer (not shown), for example, using a conformal deposition process such as a Physical Vapor Deposition (PVD) process. The deposited metal layer may comprise titanium, cobalt, or the like. An annealing process is then performed to react the metal layer with the silicon in upper source/drain regions 62U to form silicide layers 120. The remaining metal layer may then be removed, for example, by performing an etching process.

Next, (front-side) contact plugs 122 are formed. The respective process is illustrated as process 226 in the process flow 200 as shown in FIG. 17. In accordance with some embodiments, contact plugs 122 comprise a metal such as tungsten, molybdenum, ruthenium, iridium, or the like, or alloys thereof. In accordance with some embodiments, contact plugs 122 have a single-layer structure, with the entire contact plugs 122 being formed of a homogeneous material such as aforementioned.

In accordance with alternative embodiments, the formation of contact plugs 122 may include forming a barrier layer, which may comprise titanium, titanium nitride, tantalum, tantalum nitride, or the like. Next, a metallic material is deposited over and in contact with the barrier layer. The metallic material may include tungsten, cobalt, copper, nickel, molybdenum, ruthenium, iridium, or the like, or a combination thereof. After the deposition of the metallic material, a planarization process such as a CMP process or a mechanical grinding process is performed to remove excess portions of the deposited material(s), leaving contact plugs 122.

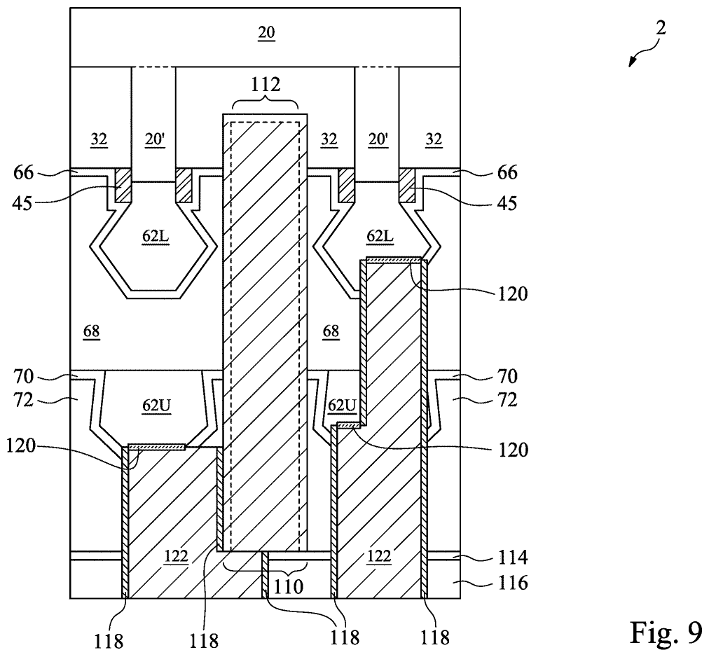

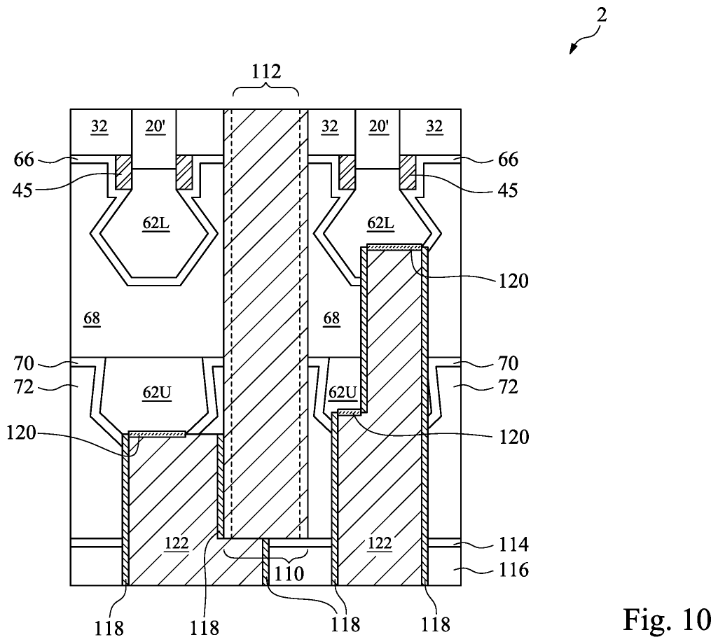

Referring to FIG. 9, wafer 2 is flipped upside down. Next, substrate 20 is thinned, for example, through a CMP process or a mechanical grinding process. The respective process is illustrated as process 228 in the process flow 200 as shown in FIG. 17. The resulting structure is shown in FIG. 10. In accordance with some embodiments, the thinning may result in the removal of STI regions 32 and the bulk substrate 20. In accordance with alternative embodiments, STI regions 32 may be left, as shown in FIG. 10. As a result of the thinning process, dielectric isolation region 110 (and contact plug 112, if formed) are also exposed.

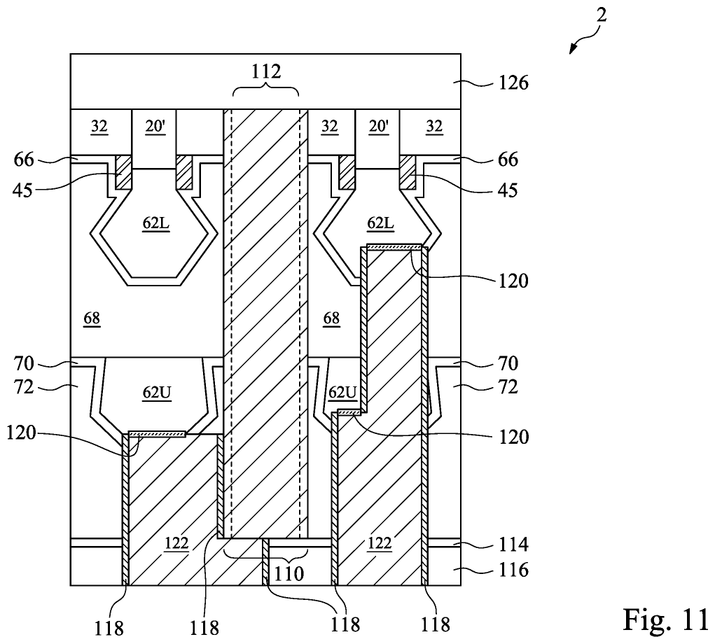

In a subsequent process, as shown in FIG. 11, dielectric layer 126 is deposited. The respective process is illustrated as process 230 in the process flow 200 as shown in FIG. 17. Dielectric layer 126 may comprise silicon oxide or other applicable dielectric materials.

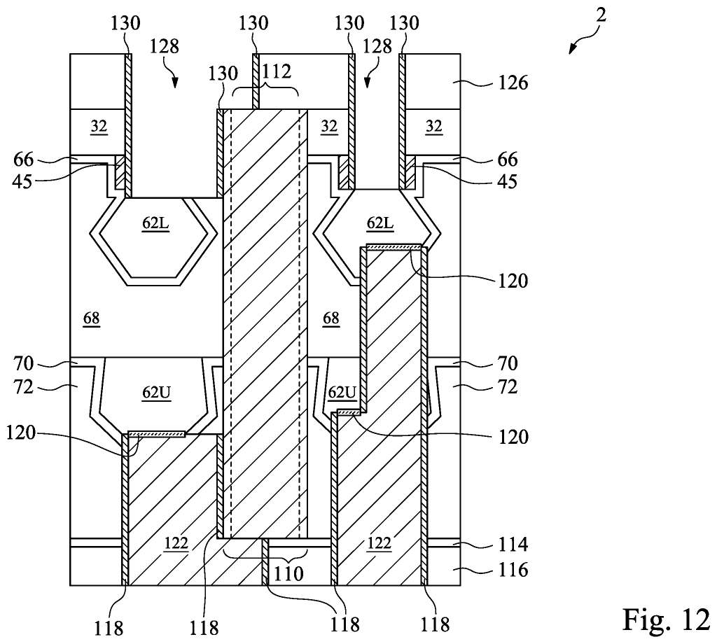

As shown in FIG. 12, (backside) contact openings 128 are formed through etching processes. The respective process is illustrated as process 232 in the process flow 200 as shown in FIG. 17. The etching is stopped on the back surfaces of lower source/drain regions 62L, and hence the lower source/drain regions 62L are exposed to the contact openings 128. Dielectric isolation region 110 (and contact plug 112, if formed) are also exposed.

In a subsequent process, dielectric liners 130 are formed. The formation process may include depositing a conformal dielectric layer through a conformal deposition process, and preforming an anisotropic etching process to remove the horizontal portions of the conformal dielectric layer. The vertical portions of the conformal dielectric layer are left as being the dielectric liners 130. The material of dielectric liners 130 may comprise silicon nitride, silicon oxynitride, silicon carbo-nitride, or the like.

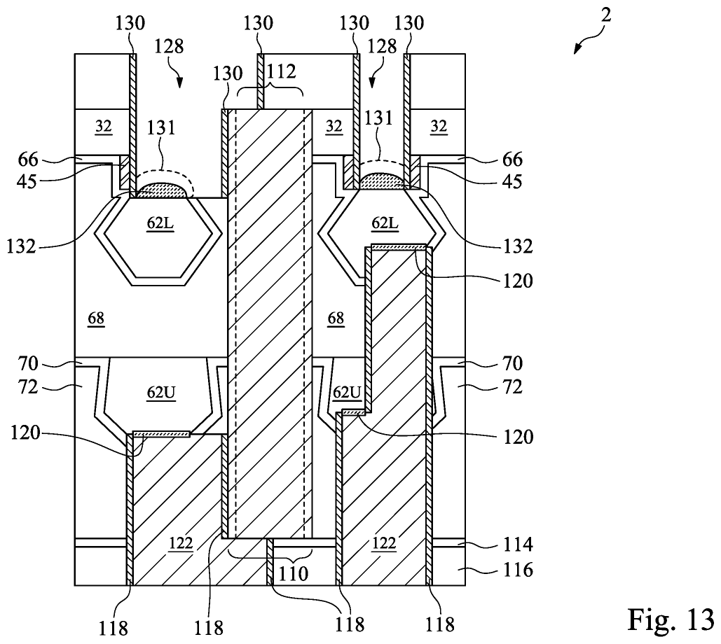

FIG. 13 illustrates a first epitaxy process for selectively forming epitaxy semiconductor layers 132. The epitaxy process is started from lower source/drain regions 62L, but not from exposed dielectric materials. The respective process is illustrated as process 234 in the process flow 200 as shown in FIG. 17. Epitaxy semiconductor layers 132 have a same conductivity type as that of lower source/drain regions 62L. For example, when lower source/drain regions 62L are p-type regions, epitaxy semiconductor layers 132 are also of p-type, and may comprise boron, indium, or the like. Conversely, when lower source/drain regions 62L are n-type regions, epitaxy semiconductor layers 132 are also of n-type, and may comprise phosphorous, antimony, arsenic, and/or the like.

The concentration of the p-type dopant (such as boron) or n-type dopant (such as phosphorous) in epitaxy semiconductor layers 132 may be higher than that in lower source/drain regions 62L in order to achieve a lower contact resistance and a lower sheet resistance. For example, the boron concentration in epitaxy semiconductor layers 132 may be in the range between about 1E20/cm³ and about 4E21/cm³. In subsequent discussion, epitaxy semiconductor layers 132 are discussed as p-type regions as an example, while it may also be n-type regions when lower source/drain regions 62L are n-type regions.

In accordance with some embodiments, epitaxy semiconductor layers 132 are formed through a low-temperature epitaxy process. The wafer temperature for forming epitaxy semiconductor layers 132 is also lower than the wafer temperature for forming lower source/drain regions 62L. For example, the wafer temperature for the formation of epitaxy semiconductor layers 132 may be lower than about 400 °C, and may be in the range between about 300 °C and about 400 °C. Due to the low temperature, the surfaces of epitaxy semiconductor layers 132 do not have clear-cut facets. For example, as shown in FIG. 13, epitaxy semiconductor layers 132 may have rounded surfaces.

In accordance with some embodiments, the epitaxy semiconductor layers 132 are higher than the exposed top ends of the sidewall portions of the first CESL 66. Also, epitaxy semiconductor layers 132 may laterally expand beyond the exposed surfaces of the lower source/drain regions 62L. For example, dashed lines 131 schematically illustrate the surfaces of the corresponding epitaxy semiconductor layers 132, which may contact the top surfaces of the sidewall portions of the first CESL 66, and may or may not contact the exposed top surface of the first ILD 68.

In accordance with some embodiments, lower source/drain regions 62L comprise SiGeB, and the germanium atomic percentage may be in the range between about 50 percent and about 75 percent. The epitaxy semiconductor layers 132 may also comprise SiGeB, and the germanium atomic percentage may also be in the same range at that of lower source/drain regions 62L, for example, in the range between about 50 percent and about 75 percent. The germanium atomic percent of epitaxy semiconductor layers 132 may be equal to, higher than, or lower than, the atomic percent of lower source/drain regions 62L.

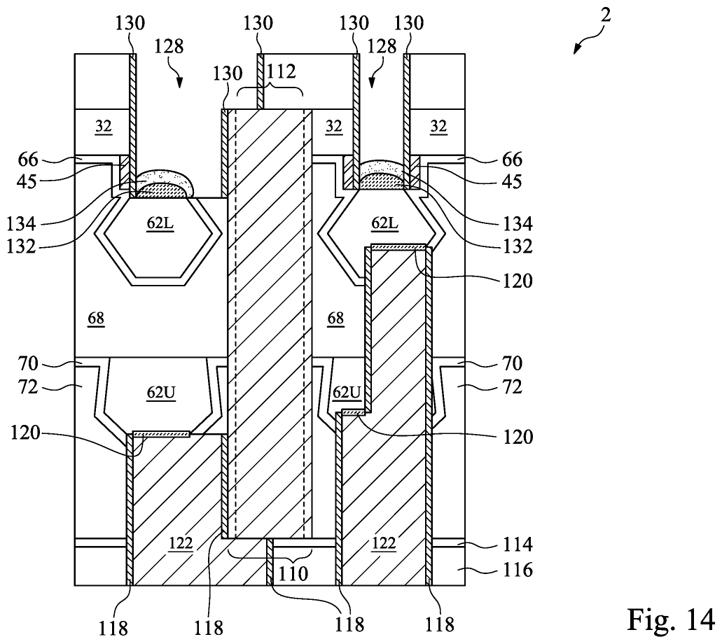

FIG. 14 illustrates the formation of epitaxy semiconductor layers 134, which is formed selectively starting epitaxy semiconductor layers 132, but not from exposed dielectric materials. The respective process is illustrated as process 236 in the process flow 200 as shown in FIG. 17. Epitaxy semiconductor layers 134 also have a same conductivity type as that of lower source/drain regions 62L. The concentration of the p-type dopant (such as boron) or n-type dopant (such as phosphorous) may be in the range between about 8E20/cm³ and about 4E21/cm³, and maybe equal to, greater than, or lower than the concentration of the dopant in epitaxy semiconductor layers 132.

In accordance with some embodiments, epitaxy semiconductor layers 134 are formed through a low-temperature epitaxy process, and the temperature may be the same as, higher than, or lower than the temperature for forming epitaxy semiconductor layers 132. For example, the wafer temperature for the formation of epitaxy semiconductor layers 134 may be lower than about 400 °C, and may be in the range between about 300 °C and about 400 °C. Epitaxy semiconductor layers 134 may also have rounded surfaces.

In accordance with some embodiments, the epitaxy semiconductor layers 134 may laterally expand beyond the exposed surfaces of the lower source/drain regions 62L. Epitaxy semiconductor layers 134 may or may not be in contact with the top surfaces of the sidewall portions of the first CESL 66, and may or may not contact the exposed top surface of the first ILD 68.

In accordance with some embodiments, epitaxy semiconductor layers 134 have a higher germanium atomic percentage than in epitaxy semiconductor layers 132, and may comprise SiGeB or GeB (without silicon therein). The germanium atomic percentage may be in the range between about 85 percent and about 100 percent.

The epitaxy semiconductor layers 134 are grown on the backside of the substrate 20 without additional wet etching process performed on backside of the substrate. Accordingly, epitaxy semiconductor layers 134 may include GeB for reducing the contact resistance, in which the GeB is not adversely oxidized by the residues resulted from the wet etching process.

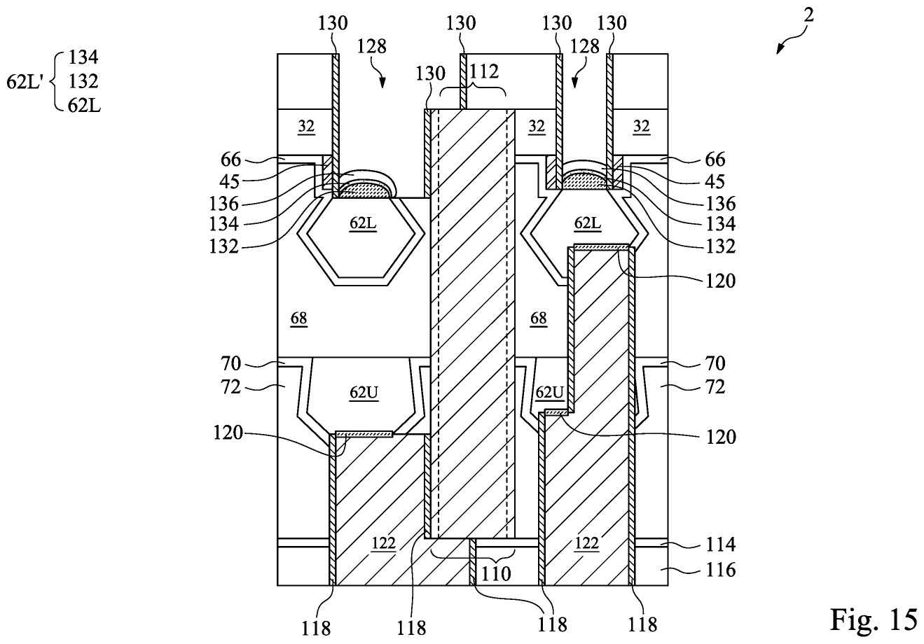

Next, as shown in FIG. 15, silicide layers 136 are formed. The respective process is illustrated as process 238 in the process flow 200 as shown in FIG. 17. The formation process may include depositing a metal layer (not shown), for example, through a conformal deposition process such as a PVD process. The deposited metal layer may comprise titanium, cobalt, or the like. An annealing process is then performed to react the metal layer with the silicon in upper epitaxy semiconductor layers 134 to form silicide layers 136. The remaining metal layer may then be removed, for example, by performing an etching process.

The silicidation process may consume the upper portions of epitaxy semiconductor layers 134, and leaves lower portions of epitaxy semiconductor layers 134 remaining. The lower source/drain regions 62L, epitaxy semiconductor layers 132, and epitaxy semiconductor layers 134 collectively form composite lower source/drain regions, which are referred to as lower source/drain regions 62L′ hereinafter.

It is desirable that the silicidation process does not fully consume epitaxy semiconductor layers 134, and the remaining portions of epitaxy semiconductor layers 134 are left to separate the silicide layers 136 from epitaxy semiconductor layers 132. Otherwise, if silicide layers 136 are in direct contact with epitaxy semiconductor layers 132, the contact resistance between the subsequently formed contact plugs 138 (FIG. 16) and lower source/drain regions 62L′ will be increased to be higher than if epitaxy semiconductor layers 134 have some portions remaining.

The thickness of the remaining portions of epitaxy semiconductor layers 134 is controlled to be not too high, and is smaller than about 2 nm. Otherwise, if epitaxy semiconductor layers 134 are too thick, the resistance of the resulting composite lower source/drain regions 62L′ will be high.

Since silicide layers 136 is formed by siliciding epitaxy semiconductor layers 134, the atomic percentage ratio APSi/APGe in silicide layers 136 may be the same as the atomic percentage ratio APSi/APGe in epitaxy semiconductor layers 134, wherein values APSi represent the atomic percentage of silicon, and values APGe represent the atomic percentage of germanium.

Referring to FIG. 16, backside contact plugs 138 are formed to fill contact openings 128 and to electrically connect to silicide layers 136. The respective process is illustrated as process 240 in the process flow 200 as shown in FIG. 17.

In accordance with some embodiments, the formation of the backside contact plugs 138 may include forming a barrier layer, which may comprise titanium nitride, tantalum nitride, or the like. Next, a metallic material is deposited over and in contact with the barrier layer. The metallic material may include tungsten, cobalt, or the like. A planarization process such as a CMP process or a mechanical grinding process is then performed to remove excess portions of the barrier layer and the metallic material, leaving backside contact plugs 138. In accordance with alternative embodiments, contact plugs 138 are barrier-less, and may include tungsten, ruthenium, or the like.

The embodiments of the present disclosure have some advantageous features. In accordance with some embodiments, by re-growing low-temperature epitaxy semiconductor layers from the backside of the lower source/drain regions, the resistance of the lower source/drain regions and the respective contact resistance are reduced. The low-temperature regrowth also improves the activation rate of the re-grown epitaxy semiconductor layers. In addition, to reduce the Schottky barrier height and achieve lower contact resistance, a germanium boron layer with high germanium atomic percentage (which may be free from or substantially free from silicon) is introduced at the silicide interface to result in a low work function and strong Fermi level pinning.

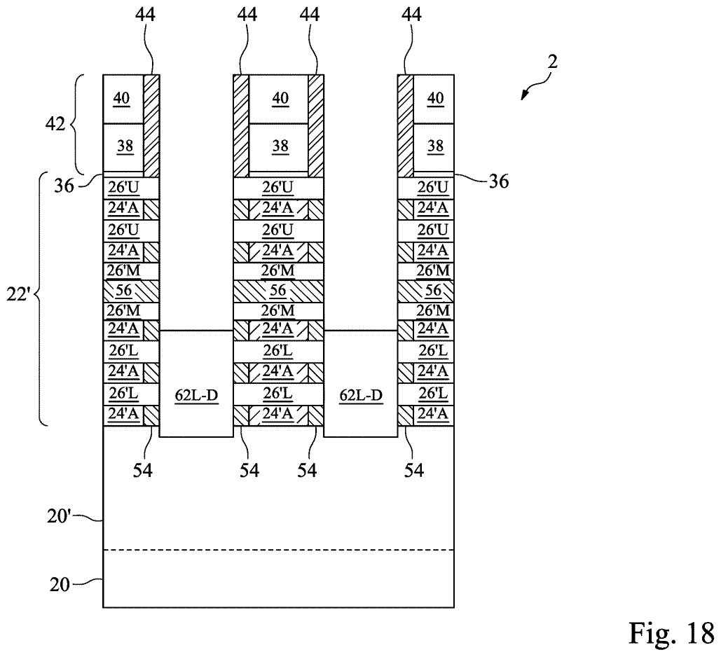

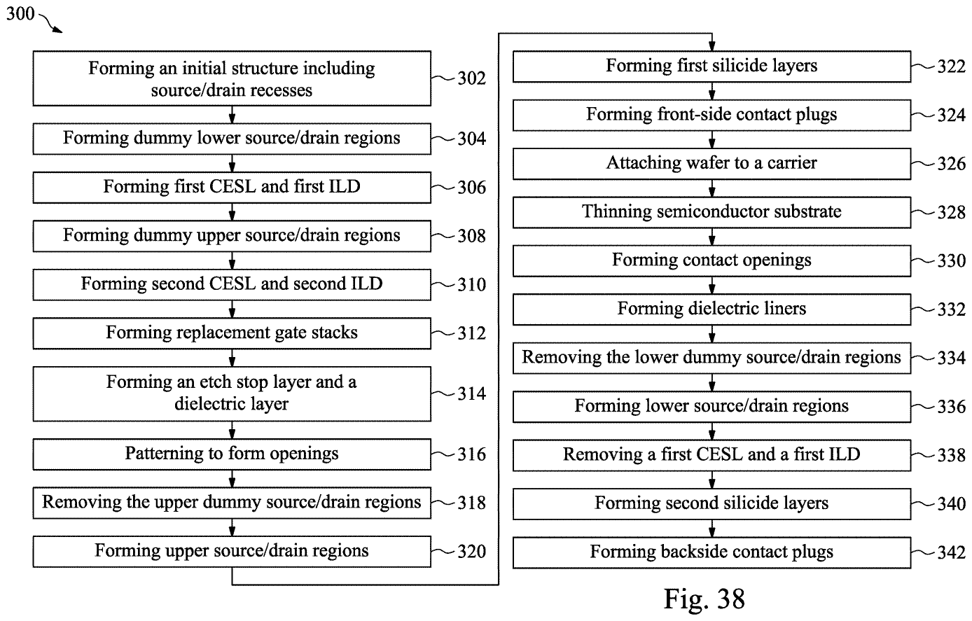

FIGS. 18 through 37 illustrate the cross-sectional views of intermediate stages in the formation of CFETs (as schematically represented in FIG. 1) in accordance with alternative embodiments. The corresponding processes are also reflected schematically in the process flow 300 as shown in FIG. 38. In accordance with these embodiments, dummy lower source/drain regions and dummy upper source/drain regions are formed, and are then replaced with replacement (epitaxy) source/drain regions.

The structures and the initial processes according to these embodiments may be essentially the same as shown and discussed referring to FIGS. 1 and 5, which are also illustrated as processes 202, 204, 205, 206, 208 and 210 in the process flow 200 as shown in FIG. 17. The respective processes are also illustrated as process 302 in the process flow 300 as shown in FIG. 38. As shown in FIG. 5, the patterned multilayer stacks 22′ have been formed. Dummy gate stacks 42 and gate spacers 44 are also formed overlying multilayer stacks 22′. Dummy nanostructures 24′B remain in multilayer stacks 22′, with the sidewalls of dummy nanostructures 24′B being exposed to source/drain recesses 46.

Dummy nanostructures 24′A are then laterally recessed, and a dielectric material is filled into the respective recesses to form inner spacers 54, which are dielectric spacers. The resulting structure is shown in FIG. 18. Dielectric isolation layers 56 are also formed to replace the dummy nanostructures 24′B.

In a subsequent process, as shown in FIG. 18, (lower) dummy source/drain regions 62L-D are formed. The respective processes are also illustrated as process 304 in the process flow 300 as shown in FIG. 38. In accordance with some embodiments, the material of dummy source/drain regions 62L-D may comprise an intrinsic semiconductor material such as SiGe, Si, SiC, or the like, wherein no p-type dopant is doped, and no n-type dopant is doped. When Si is used, other elements may be added, so that in the subsequent removal of dummy source/drain regions 62U-D, the selectivity between dummy source/drain regions 62L-D and semiconductor nanostructures 26′U is high.

In accordance with alternative embodiments, the semiconductor material may be a p-type semiconductor material comprising a p-type dopant such as boron. In accordance with yet alternative embodiments, the semiconductor material may be an n-type semiconductor material comprising an n-type dopant such as phosphorous.

In accordance with some embodiments, dummy source/drain regions 62L-D comprise an epitaxy material, which has a crystalline structure. The wafer temperature for forming dummy source/drain regions 62L-D may be a relatively high temperature, for example, in a range between about 550 °C and about 800 °C. Alternatively, the wafer temperature for forming dummy source/drain regions 62L-D may be a relatively low temperature, for example, in a range between about 300 °C and about 550 °C.

In accordance with alternative embodiments, dummy source/drain regions 62L-D has a polycrystalline structure or an amorphous structure. The wafer temperature for forming dummy source/drain regions 62L-D may be low, for example, lower than about 300 °C. The top surface of dummy source/drain regions 62L-D are controlled to be higher than the topmost one of lower semiconductor nanostructures 26′L.

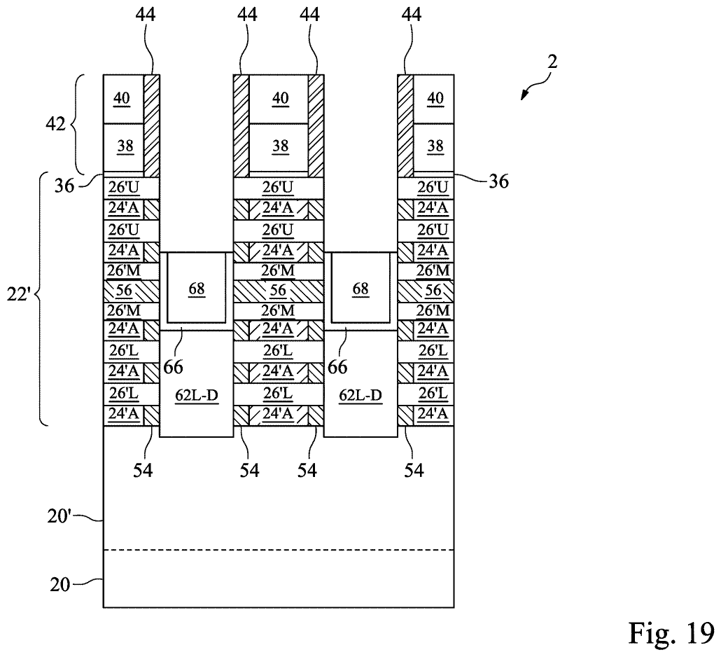

Referring to FIG. 19, a first contact etch stop layer (CESL) 66 and a first ILD 68 are formed. The respective processes are also illustrated as process 306 in the process flow 300 as shown in FIG. 38. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, PECVD, or FCVD. The applicable dielectric material of the first ILD 68 may include PSG, BSG, BPSG, USG, silicon oxide, or the like.

The formation processes may include depositing a conformal CESL layer, depositing a material for ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26′U are exposed.

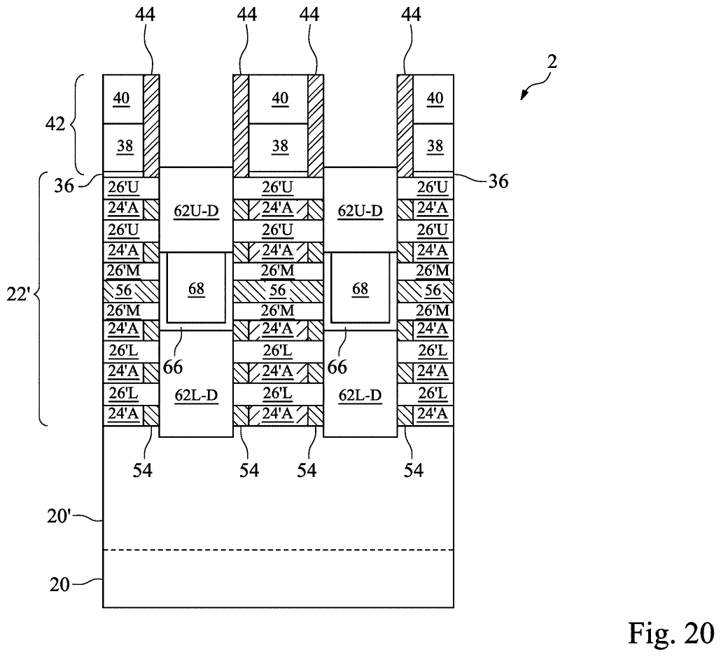

In a subsequent process, as shown in FIG. 20, dummy source/drain regions 62U-D are formed. The respective processes are also illustrated as process 308 in the process flow 300 as shown in FIG. 38. In accordance with some embodiments, the material of dummy source/drain regions 62U-D may comprise an intrinsic semiconductor material such as SiGe, Si, SiC, or the like, wherein no p-type dopant is doped, and no n-type dopant is doped. When Si is used, other elements may be added to increase its selectivity with semiconductor nanostructures 26′U in the subsequent removal of dummy source/drain regions 62U-D.

In accordance with alternative embodiments, the semiconductor material of dummy source/drain regions 62U-D may be a p-type semiconductor material comprising a p-type dopant such as boron. In accordance with yet alternative embodiments, the semiconductor material may be an n-type semiconductor material comprising an n-type dopant such as phosphorous.

The material of dummy source/drain regions 62U-D may be the same or different from the material of dummy source/drain regions 62L-D. In accordance with some embodiments, dummy source/drain regions 62U-D comprises an epitaxy semiconductor material, which has a crystalline structure. The wafer temperature for forming dummy source/drain regions 62U-D may be a relatively high temperature, for example, in a range between about 550 °C and about 800 °C. Alternatively, the wafer temperature for forming dummy source/drain regions 62U-D may be a relatively low temperature, for example, in a range between about 300 °C and about 550 °C.

In accordance with alternative embodiments, dummy source/drain regions 62U-D has a polycrystalline structure or an amorphous structure. The wafer temperature for forming dummy source/drain regions 62U-D may be low, for example, lower than about 300 °C. The top surface of dummy source/drain regions 62U-D are controlled to be higher than the topmost one of the upper semiconductor nanostructures 26′U.

If dummy source/drain regions 62U-D is doped, the conductivity type (and the dopant) of the dummy source/drain regions 62U-D may be opposite to or the same as the conductivity type (and the dopant) of the lower epitaxial source/drain regions 62L-D. Alternatively, one of the dummy source/drain regions 62U-D and dummy source/drain regions 62L-D is doped, while the other is intrinsic.

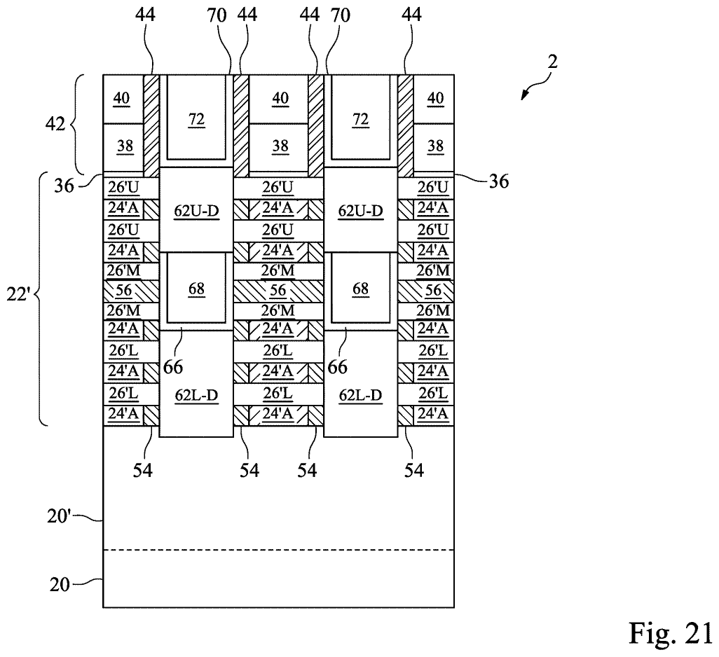

Referring to FIG. 21, a second CESL 70 and a second ILD 72 are formed. The respective process is illustrated as process 310 in the process flow 300 as shown in FIG. 38. The materials and the formation methods may be similar to the materials and the formation methods of first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the dummy gate stacks 42 are coplanar (within process variations). The planarization process may remove masks 40, or leave hard masks 40 unremoved.

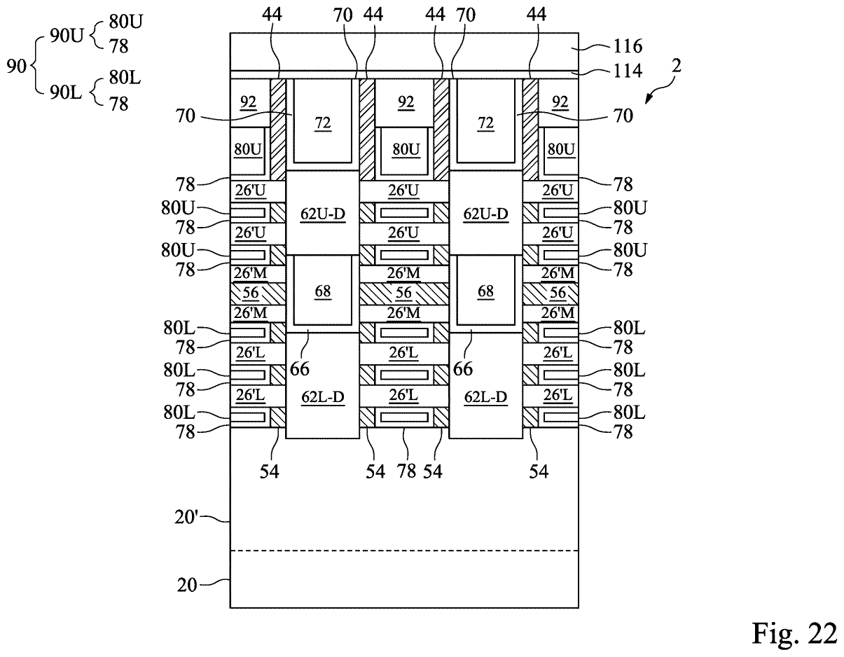

Replacement gate stacks 90 are then formed, and the resulting structure is shown in FIG. 22. The respective processes are also illustrated as process 312 in the process flow 300 as shown in FIG. 38. To form the replacement gate stacks 90, dummy gate stacks 42 are first removed in one or more etching processes, so that recesses (FIG. 22, occupied by gate stacks 90) are formed. Each of the recesses exposes and/or overlies portions of multilayer stacks 22′.

The remaining portions of the dummy nanostructures 24′A (FIG. 21) are then removed through etching, so that the recesses extend between the semiconductor nanostructures 26′. In the etching process, the dummy nanostructures 24′A is etched at a faster rate than the semiconductor nanostructures 26′, the dielectric isolation layers 56, and the inner spacers 54. The etching may be isotropic. For example, when the dummy nanostructures 24′A are formed of silicon-germanium, and the semiconductor nanostructures 26′ are formed of silicon, the etch process may include a wet etch process using tetramethylammonium hydroxide (TMAH), ammonium hydroxide (NH₄OH), or the like.

The formation of replacement gate stacks 90 includes forming gate dielectrics 78, which are formed in the recesses, and are formed on the exposed semiconductor nanostructures 26′. The gate dielectrics 78 are formed on the exposed surfaces of the exposed features including the semiconductor nanostructures 26′ and the gate spacers 44. The gate dielectrics 78 wrap around all (e.g., four) sides of the semiconductor nanostructures 26′.

Each of the gate dielectrics 78 may include an interfacial layer, which may include an oxide such as silicon oxide. The interfacial layer may be formed through a thermal oxidation process and/or a deposition process. The gate dielectrics 78 may also include high-k dielectric layers, which have a high dielectric constant (high-k) value greater than, for example, about 7.0. High-k dielectric layers may be formed of or comprise a metal oxide or a silicate of a metal selected from hafnium, zirconium, barium, titanium, lead, and combinations thereof.

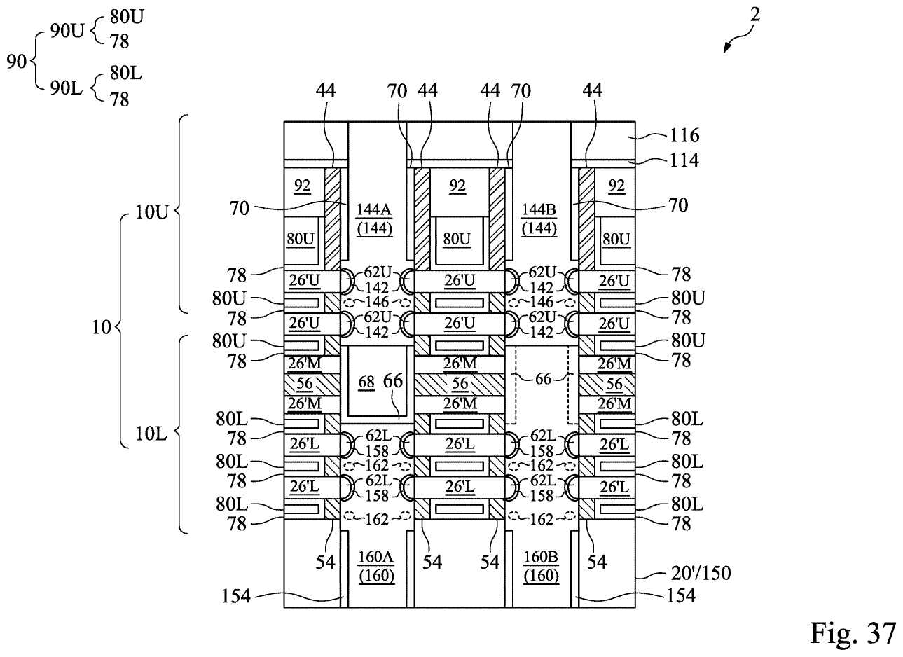

Gate electrodes 80L and 80U are also formed. In the formation process, conductive layers are first formed on the high-k dielectric layer, and the remaining portions of the recesses are filled. Each of gate electrodes 80L and 80U may include a metal-containing material such as TiN, TaN, TiAl, TiAlC, cobalt, ruthenium, aluminum, tungsten, combinations thereof, and/or multilayers thereof. The gate electrodes 80L and 80U may provide work-functions suitable to the resulting lower FETs (lower transistors) 10L (FIG. 37) and upper FETs (upper transistors) 10U (FIG. 37). The gate electrodes 80L and 80U may be common gates formed in a same formation process, or may be electrically disconnected from each other and formed in separate processes.

The resulting gate stacks 90L include gate dielectrics 78 and gate electrodes 80L. The resulting gate stacks 90U include gate dielectrics 78 and gate electrodes 80U. Dielectric hard masks 92 are formed over the gate stacks 90U.

Further referring to FIG. 22, etch stop layer 114 and dielectric layer 116 are formed. The respective process is illustrated as process 314 in the process flow 300 as shown in FIG. 38. Etch stop layer 114 may comprise AlN, AlO, SiOC, or the like, or multilayers thereof. Dielectric layer 116 may comprise silicon oxide, silicon nitride, silicon oxynitride, silicon carbide, or the like.

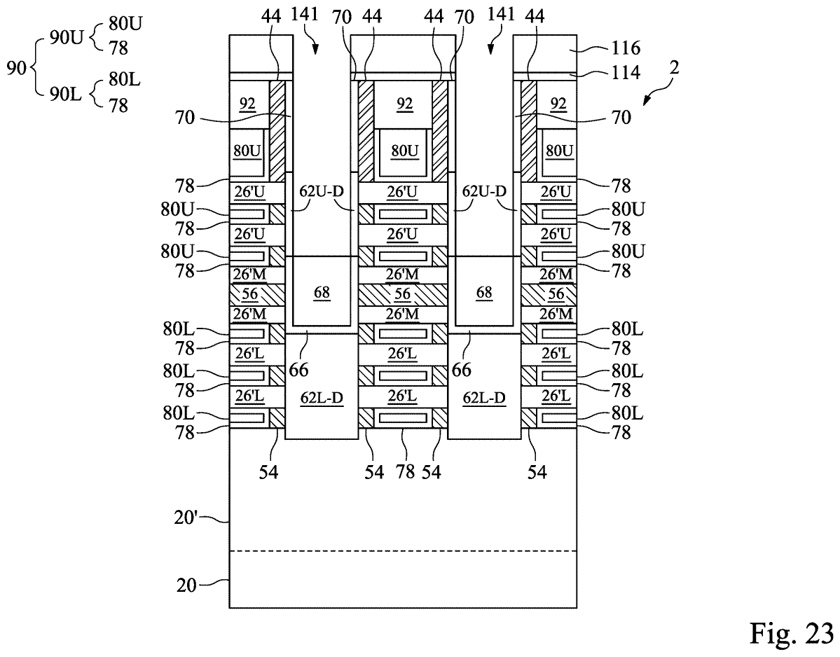

Next, as shown in FIG. 23, patterning processes are performed to etch dielectric layer 116, etch stop layer 114, and second ILD 72, so that openings 141 are formed. The respective process is illustrated as process 316 in the process flow 300 as shown in FIG. 38. In accordance with some embodiments, the bottom portions of the second CESL 70 are etched. The etching may be anisotropic, so that the sidewall portions of the second CESL 70 remain as a dielectric isolation layer.

In accordance with alternative embodiments, instead of using the vertical portions of the second CESL 70 as the dielectric isolation layer, the vertical portions of the second CESL 70 are also etched. A conformal deposition process is then performed, followed by an anisotropic etching process to form the dielectric isolation layer.

After the etching of the sidewall portions of the second CESL 70, the dummy source/drain regions 62U-D are also etched. Since the etching may be anisotropic, there may be (or may not be) some portions of the dummy source/drain regions 62U-D left directly underlying the vertical portions of the second CESL 70. After the etching of dummy source/drain regions 62U-D, the first ILD 68 is exposed, and the etching is stopped on the top surface of the first ILD 68.

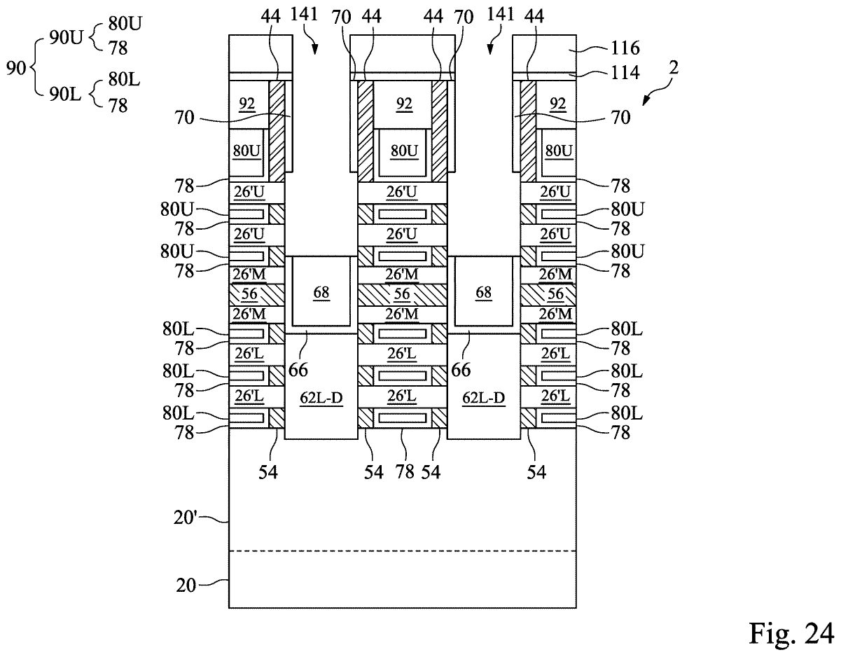

An etching process is then performed to remove the remaining portions (if any) of the dummy source/drain regions 62U-D. The respective process is illustrated as process 318 in the process flow 300 as shown in FIG. 38. The resulting structure is shown in FIG. 24. The etching is isotropic, so that the sidewalls of semiconductor nanostructures 26′U are exposed. Due to the selection of the materials of dummy source/drain regions 62U-D to be different from that of semiconductor nanostructures 26′U, semiconductor nanostructures 26′U are substantially un-etched.

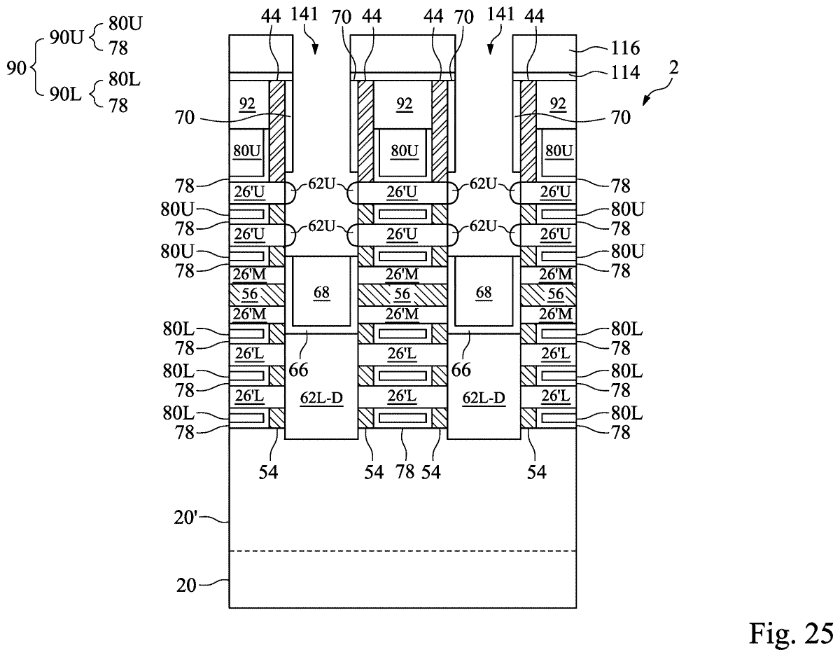

FIG. 25 illustrates the epitaxy regrowth process to form upper epitaxial source/drain regions 62U. The respective process is illustrated as process 320 in the process flow 300 as shown in FIG. 38. The upper epitaxial source/drain regions 62U are in contact with the upper semiconductor nanostructures 26′U and are not in contact with the lower semiconductor nanostructures 26′L. In accordance with some embodiments, the upper epitaxial source/drain regions 62U grown from neighboring upper semiconductor nanostructures 26′U are spaced apart from each other. In subsequent discussion, the upper epitaxial source/drain regions 62U grown from neighboring upper semiconductor nanostructures 26′U are also referred to as the portions of an upper semiconductor nanostructure 26′U.

The upper epitaxial source/drain regions 62U are epitaxially grown, and have a conductivity type that is suitable for the device type (p-type or n-type) of the upper nanostructure-FETs. When upper epitaxial source/drain regions 62U are n-type source/drain regions, the respective material may include silicon or carbon-doped silicon, which is doped with an n-type dopant such as phosphorous, arsenic, or the like. When upper epitaxial source/drain regions 62U are p-type source/drain regions, the respective material may include silicon or silicon germanium, which is doped with a p-type dopant such as boron, indium, or the like.

The temperature of the formation of upper epitaxial source/drain regions 62U is controlled to be not too high and not too low. In accordance with some embodiments, the temperature for forming the upper epitaxial source/drain regions 62U may be a relatively low temperature, which may be lower than about 400 °C, and may be in the range between about 300 °C and about 400 °C. When the temperature is too high such as higher than about 400 °C, the reliability of the gate stacks may be sacrificed. When the temperature is too low such as lower than about 300 °C, the upper epitaxial source/drain regions 62U may have an amorphous structure.

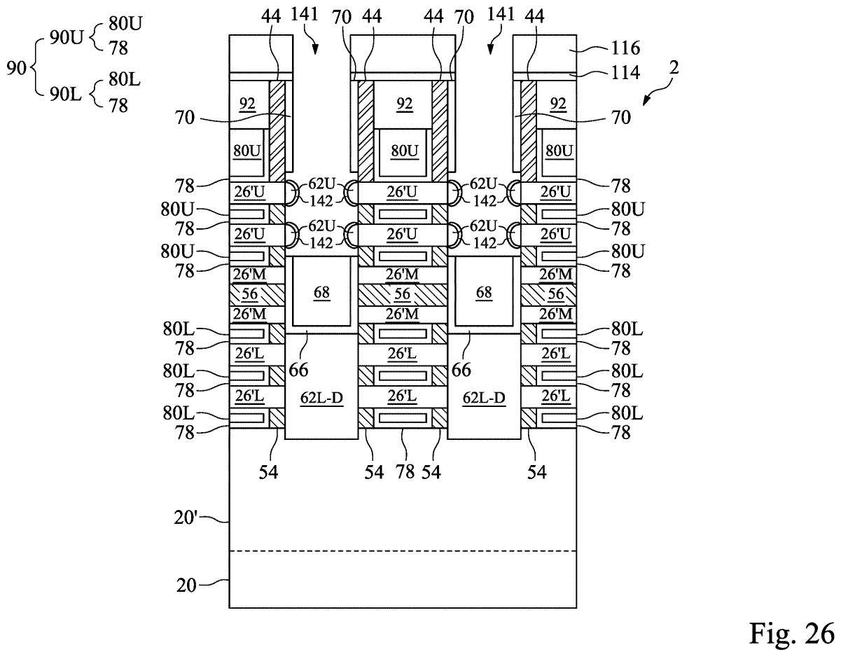

Referring to FIG. 26, silicide layers 142 are formed. The respective process is illustrated as process 322 in the process flow 300 as shown in FIG. 38. The formation process may include depositing a metal layer (not shown), for example, through a conformal deposition process such as a PVD process. The deposited metal layer may comprise titanium, cobalt, or the like. An annealing process is then performed to react the metal layer with the silicon in the upper epitaxial source/drain regions 62U to form silicide layers 142. The remaining metal layer may then be removed, for example, by performing an etching process.

The silicidation process consumes the outer portions of upper epitaxial source/drain regions 62U, and leaves the inner portions of upper epitaxial source/drain regions 62U remaining. The portions of the silicide layers 142 grown from neighboring (upper ones and the corresponding lower ones) upper epitaxial source/drain regions 62U may be discrete, or may be joined with each other, depending on the sizes of the upper epitaxial source/drain regions 62U and the silicide layers 142.

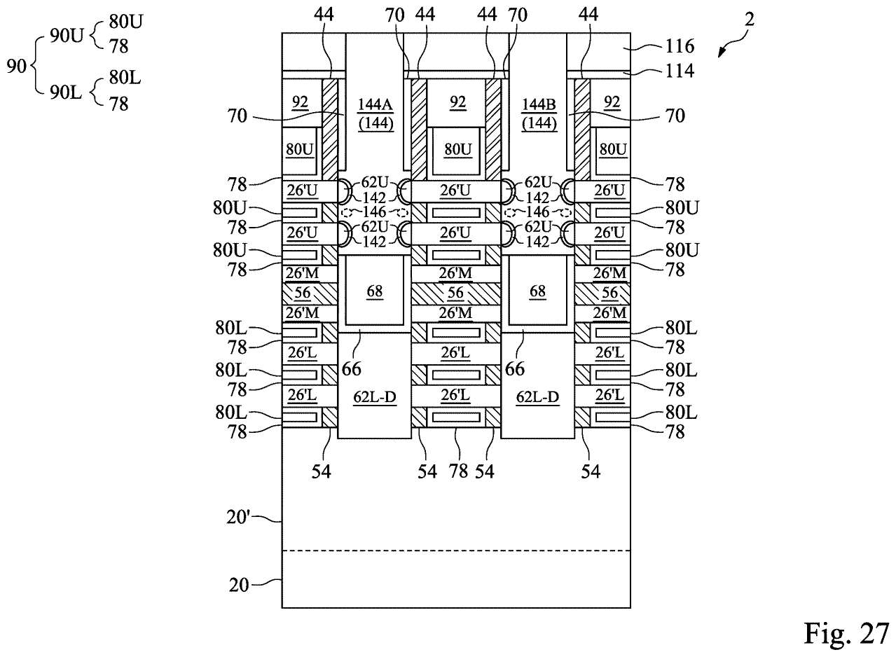

Referring to FIG. 27, (front-side) contact plugs 144 (including contact plugs 144A and 144B) are formed to fill openings 141 and to electrically connect to silicide layers 142. The respective process is illustrated as process 324 in the process flow 300 as shown in FIG. 38.

In accordance with some embodiments, the formation of the contact plugs 144 may include forming a barrier layer, which may comprise titanium nitride, tantalum nitride, or the like. Next, a metallic material is deposited over and in contact with the barrier layer. The metallic material may include tungsten, cobalt, or the like. A planarization process such as a CMP process or a mechanical grinding process is then performed to remove excess portions of the barrier layer and the metallic material, leaving contact plugs 144. In accordance with alternative embodiments, contact plugs 144 are barrier-less, and may include tungsten, ruthenium, or the like.

The deposition process for forming contact plugs 144 may include a conformal deposition process or a bottom-up deposition process. When the bottom-up deposition process is performed, a metal seed layer may be deposited. The metal seed layer may be recessed so that only the portions at the bottoms of the openings 141 are left. The recessing may be achieved by depositing a sacrificial layer (such as a cross-linked photoresist), planarizing and then recessing the sacrificial layer to cover the bottom portion of the metal seed layer, etching the exposed sidewall portions of the metal seed layer, and removing the sacrificial layer. A metal is then deposited starting from the bottom portion of the metal seed layer.

In accordance with some embodiments, for example, when a conformal deposition process is performed to form the contact plugs 144, voids 146 may be formed, which may be located in the regions that are overlapped by silicide layers 142. In other embodiments, no voids are formed.

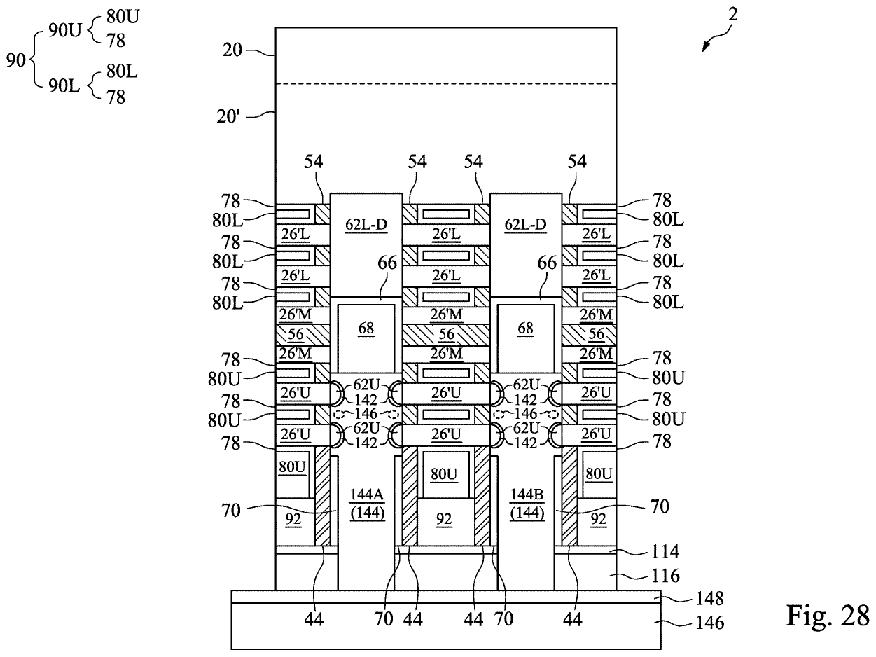

Referring to FIG. 28, wafer 2 is flipped upside down, and is attached to carrier 146 through release film 148. The respective process is illustrated as process 326 in the process flow 300 as shown in FIG. 38. Carrier 146 may be a glass carrier, a silicon wafer, an organic carrier, or the like. Release film 148 may be formed of a polymer-based material (such as a Light-To-Heat-Conversion (LTHC) material), which is capable of being decomposed under a heat-carrying radiation such as a laser beam, so that carrier 146 may be de-bonded from the overlying structures that will be formed in subsequent processes.

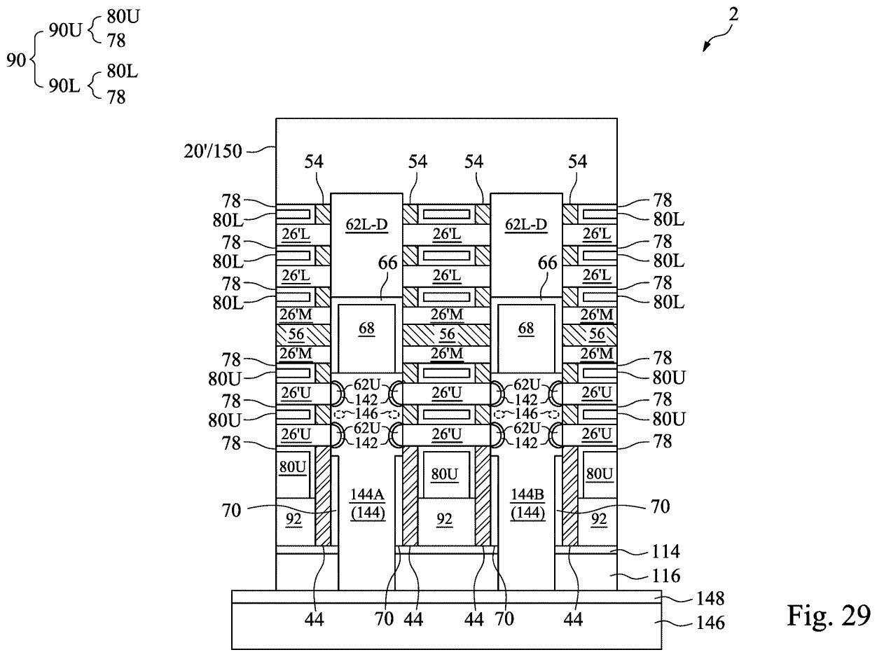

Referring to FIG. 29, wafer 2 is thinned from backside. The respective process is illustrated as process 328 in the process flow 300 as shown in FIG. 38. The thinning may be performed through a CMP process or a mechanical grinding process. In accordance with some embodiments, the backside thinning results in the bulk substrate 20 to be removed, and portions of semiconductor strips 20′ are left. STI regions 32, which are in other planes that are not illustrated, may have some portions left.

In accordance with some embodiments, the semiconductor strips 20′ are replaced with a dielectric material, forming dielectric layer 150. The replacement may include etching semiconductor strips 20′, depositing a dielectric material such as silicon oxide between neighboring STI regions 32, and performing a planarization process to remove excess portions of the dielectric material. In accordance with alternative embodiments, the semiconductor strips 20′ are not replaced. Accordingly, the corresponding regions are denoted as regions “20′/150” to represent that these regions may be semiconductor strips 20′ or dielectric regions 150.

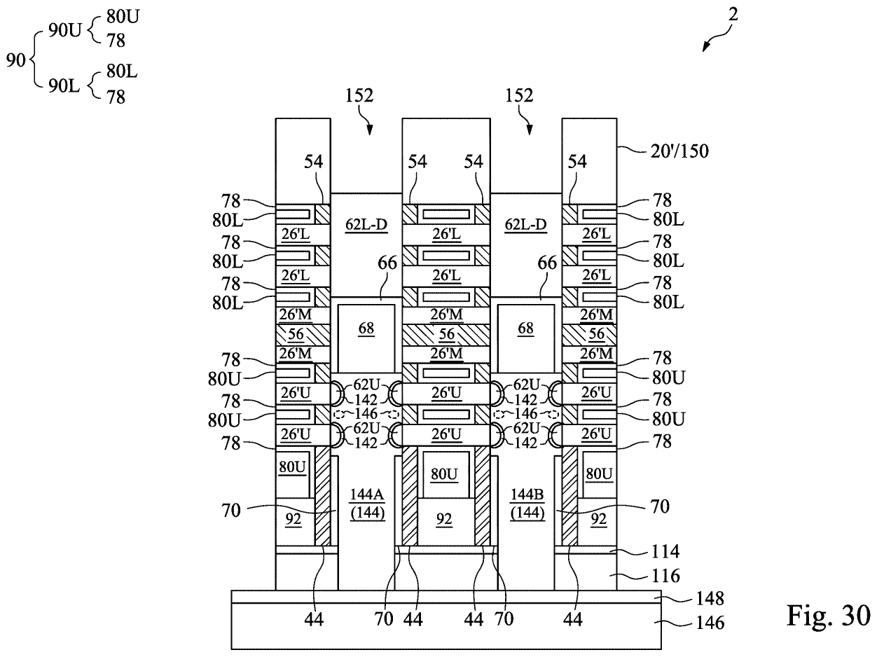

Referring to FIG. 30, an etching process is performed to remove some portions of regions 20′/150, and forming openings 152. The respective process is illustrated as process 330 in the process flow 300 as shown in FIG. 38. Lower dummy semiconductor regions 62L-D are thus exposed.

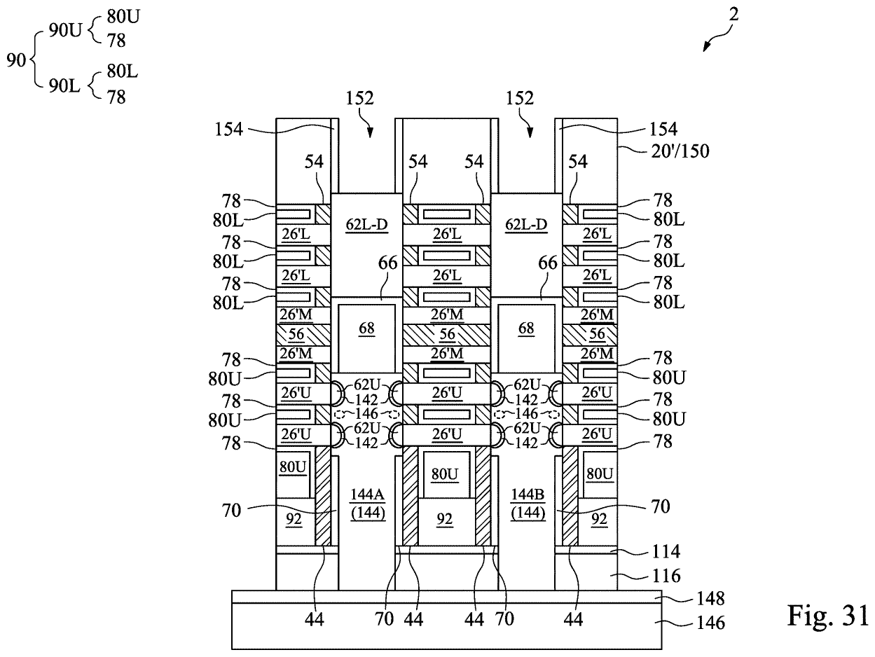

FIG. 31 illustrates the formation of dielectric liners 154 in accordance with some embodiments. The respective process is illustrated as process 332 in the process flow 300 as shown in FIG. 38. The formation process may include a conformal deposition process to deposit a conformal dielectric layer, and an anisotropic etching process to remove the horizontal portions of the conformal dielectric layer. The vertical portions of the conformal dielectric layer are left as the dielectric liners 154. Dielectric liners 154 may comprise silicon nitride, silicon oxynitride, silicon oxy carbo-nitride, or the like.

In accordance with some embodiments in which the semiconductor strips have been replaced as dielectric regions 150, the formation of the dielectric liners 154 may be skipped.

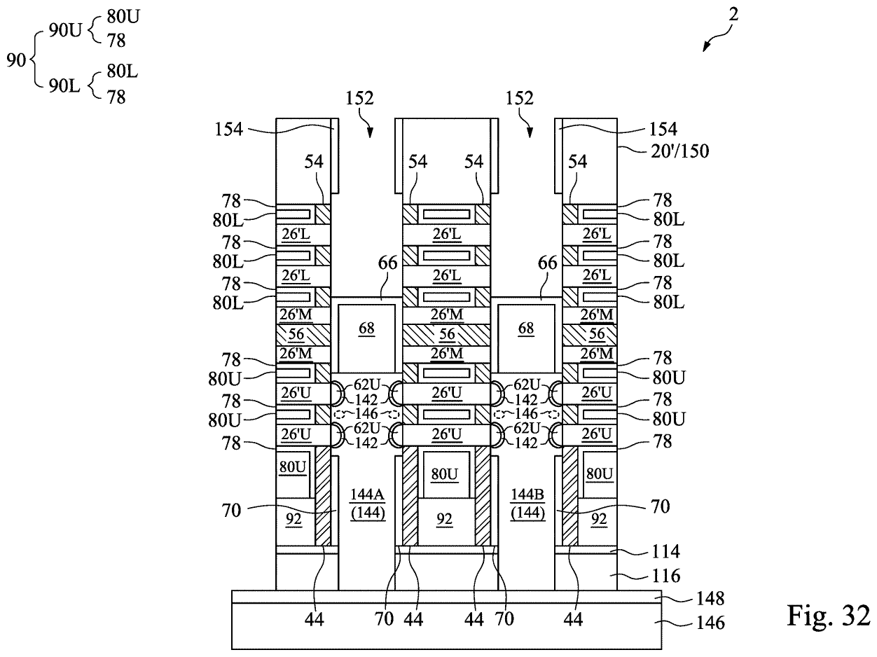

An etching process is then performed to remove dummy source/drain regions 62U-D. The respective process is illustrated as process 334 in the process flow 300 as shown in FIG. 38. The resulting structure is shown in FIG. 32. The etching may include an isotropic etching process, so that the entirety of the dummy source/drain regions 62L-D are removed, and the sidewalls of semiconductor nanostructures 26′L are exposed. The first CESL 66 may be used as a part of the etch stop layer. Due to the selection of the materials of dummy source/drain regions 62L-D to be different from that of semiconductor nanostructures 26′L, semiconductor nanostructures 26′L are substantially un-etched.

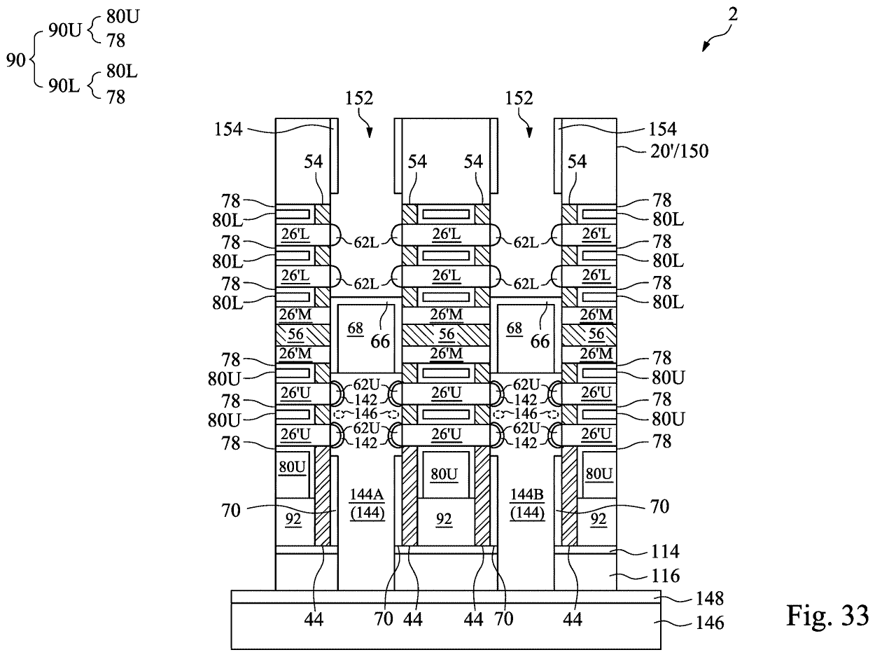

FIG. 33 illustrates the epitaxy regrowth process to form lower epitaxial source/drain regions 62L. The respective process is illustrated as process 336 in the process flow 300 as shown in FIG. 38. The lower epitaxial source/drain regions 62L are in contact with the lower semiconductor nanostructures 26′L and are not in contact with the upper semiconductor nanostructures 26∝U.

In accordance with some embodiments, the lower epitaxial source/drain regions 62L grown from neighboring lower semiconductor nanostructures 26′L are spaced apart from each other. In subsequent discussion, the lower epitaxial source/drain regions 62L grown from neighboring lower semiconductor nanostructures 26′L are also referred to as the portions of a lower semiconductor nanostructure 26′L.

The lower epitaxial source/drain regions 62L are epitaxially grown, and have a conductivity type that is suitable for the device type (p-type or n-type) of the lower nanostructure-FETs. When the lower epitaxial source/drain regions 62L are p-type source/drain regions, the respective material may include silicon or silicon germanium, which is doped with a p-type dopant such as boron, indium, or the like. When the lower epitaxial source/drain regions 62L are n-type source/drain regions, the respective material may include silicon or carbon-doped silicon, which is doped with an n-type dopant such as phosphorous, arsenic, or the like.

The temperature for the formation of lower epitaxial source/drain regions 62L is controlled to be not too high and not too low. In accordance with some embodiments, the temperature for forming the lower epitaxial source/drain regions 62L may be a relatively low temperature, which may be lower than about 400 °C, and may be in the range between about 300 °C and about 400 °C. When the temperature is too high such as higher than about 400°C, the reliability of back-end-of-line structures may be sacrificed. When the temperature is too low such as lower than about 300 °C, the lower epitaxial source/drain regions 62L may have an amorphous structure.

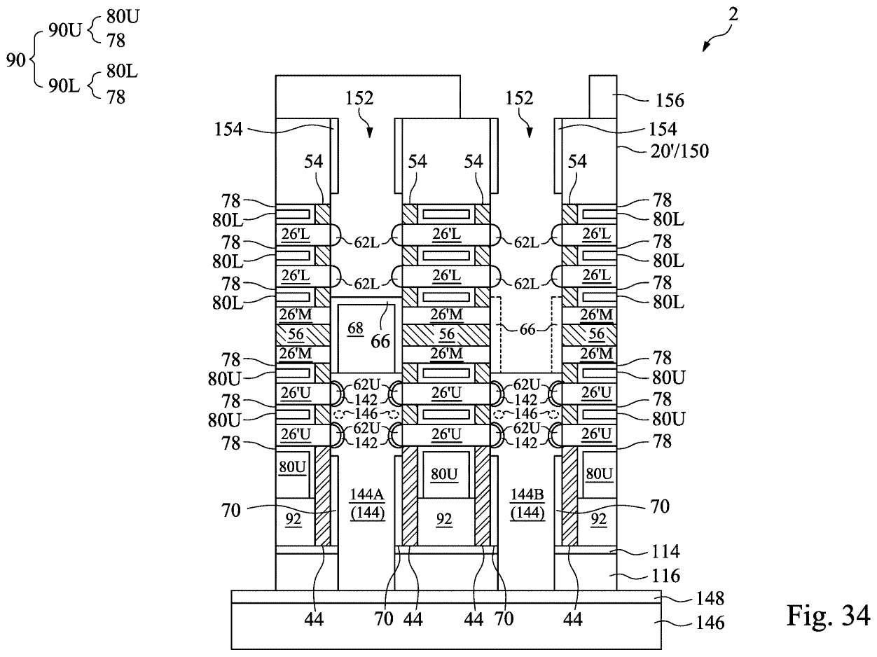

FIG. 34 illustrates the removal of the horizontal portion of one of first CESLs 66 and one of the first ILDs 68 from one of contact openings 152 in accordance with some embodiments. The sidewall portions of the first CESL 66 may be removed, or may remain un-removed. Accordingly, the sidewall portions of the first CESL 66 are illustrated as being dashed to indicate that these portions may or may not exist. The respective process is illustrated as process 338 in the process flow 300 as shown in FIG. 38. The removal is performed by forming a patterned etching mask (such as photoresist) 156, and etching the first CESL 66 and first ILD 68 through the respective contact opening 152 that is not filled with the patterned etching mask 156. Contact plug 144B is thus exposed. After the etching process, the patterned etching mask 156 is removed.

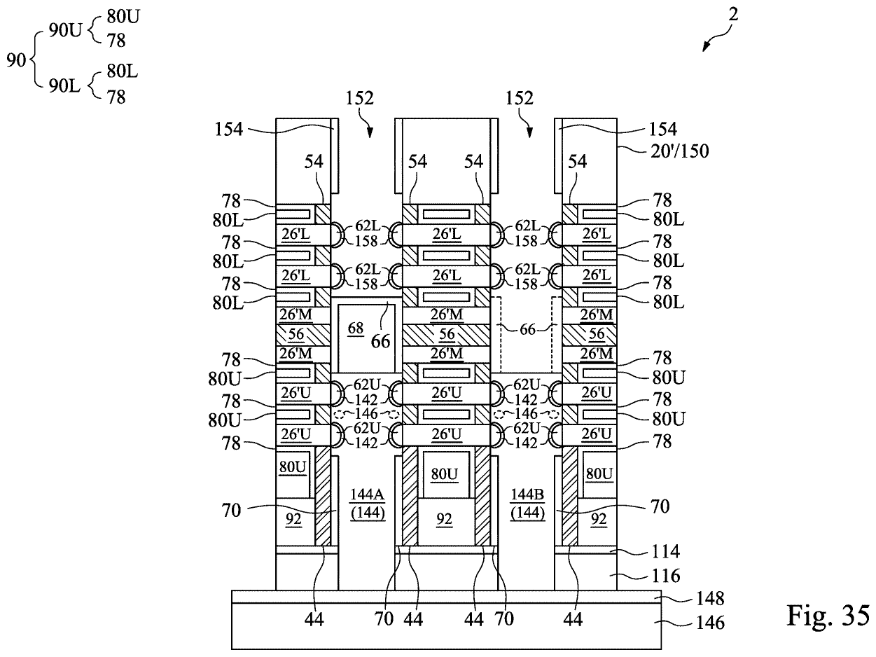

Referring to FIG. 35, silicide layers 158 are formed. The respective process is illustrated as process 340 in the process flow 300 as shown in FIG. 38. The formation process may include depositing a metal layer (not shown), for example, through a conformal deposition process such as a PVD process. The deposited metal layer may comprise titanium, cobalt, or the like. An annealing process is then performed to react the metal layer with the silicon in the lower epitaxial source/drain regions 62L to form silicide layers 158. The remaining metal layer may then be removed, for example, by performing an etching process.

The silicidation process consumes the outer portions of lower epitaxial source/drain regions 62L, and leaving the inner portions of lower epitaxial source/drain regions 62L remaining. The silicide layers 158 on neighboring (upper ones and the respective lower ones) lower epitaxial source/drain regions 62L may be separate from each other, with spaces left in between, or may be joined with each other.

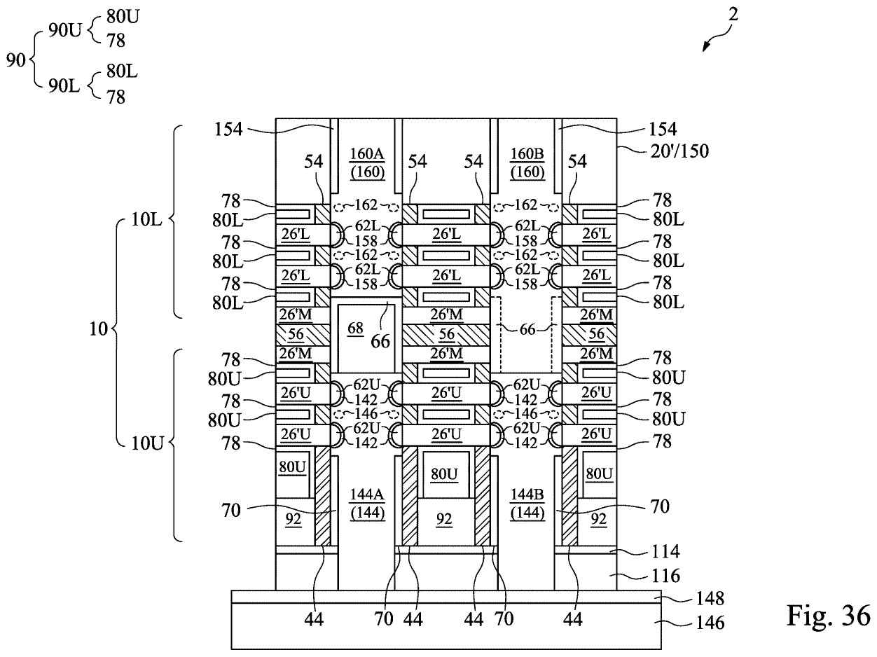

Referring to FIG. 36, (backside) contact plugs 160 (including contact plugs 160A and 160B) are formed to fill openings 152 and to electrically connect to silicide layers 158. The respective process is illustrated as process 342 in the process flow 300 as shown in FIG. 38. In accordance with some embodiments, the formation of the contact plugs 160 may include forming a barrier layer, which may comprise titanium nitride, tantalum nitride, or the like. Next, a metallic material is deposited over and in contact with the barrier layer. The metallic material may include tungsten, cobalt, or the like. A planarization process such as a CMP process or a mechanical grinding process is then performed to remove excess portions of the barrier layer and the metallic material, leaving contact plugs 160. In accordance with alternative embodiments, contact plugs 160 are barrier-less, and may include tungsten, ruthenium, or the like.

The deposition process for forming contact plugs 160 may include a conformal deposition process or a bottom-up deposition process. When the bottom-up deposition process is performed, a metal seed layer may be deposited. The metal seed layer may be recessed so that only the portions at the bottoms of the openings 152 are left. The recessing may be achieved by depositing a sacrificial layer (such as a cross-linked photoresist), planarizing and then recessing the sacrificial layer to cover the bottom portion of the metal seed layer, etching the exposed sidewall portions of the metal seed layer, and removing the sacrificial layer. A metal is then deposited starting from the bottom portion of the metal seed layer.

In accordance with some embodiments, for example, when a conformal deposition process is performed, voids 162 may be formed, which may be located in the regions that are overlapped by (and/or overlying) silicide layers 158. In other embodiments, no voids are formed.

In accordance with some embodiments, contact plug 160B is physically joined to contact plug 144B. The interface between contact plugs 144B and 160B may be distinguishable from each other. In the embodiments in which contact plugs 144B and 160B comprise barriers, the barriers may have U-shapes, with the U-shape of the barrier of contact plug 144B having an opening facing down, and the U-shape of the barrier of contact plug 160B having an opening facing up. The CFET 10 comprising the upper FET 10U and lower FET 10L are thus formed.

In a subsequent process, wafer 2 is de-bonded from carrier 146, for example, by projecting a laser beam on release film 148, so that the release film 148 is decomposed, releasing wafer 2 from carrier 146. FIG. 37 illustrates a resulting wafer 2, which is shown with upper FET 10U overlapping lower FET 10L.

The embodiments of the present disclosure have some advantageous features. In accordance with some embodiments, dummy source/drain regions are formed first to facilitate self-alignment of the subsequently formed low-temperature epitaxy source/drain regions. By adopting low-temperature epitaxy to form source/drain regions, the resistance of the source/drain regions and the respective contact plugs are reduced. The low-temperature regrowth also improves the activation rate of the re-grown epitaxy source/drain regions.

In accordance with some embodiments of the present disclosure, a method comprises forming a lower transistor comprising forming a lower source/drain region over a semiconductor substrate, wherein the lower source/drain region comprises a bottom side facing the semiconductor substrate; forming an upper transistor comprising forming an upper source/drain region over the lower source/drain region; thinning the semiconductor substrate; forming a contact opening to expose the bottom side of the lower source/drain region; performing a first epitaxy process to grow a first semiconductor layer on the lower source/drain region; and forming a silicide layer, wherein the silicide layer is electrically connected to the lower source/drain region through the first semiconductor layer.

In an embodiment, the method further comprises performing a second epitaxy process to grow a second semiconductor layer over the first semiconductor layer. In an embodiment, the silicide layer is formed by siliciding a portion of the second semiconductor layer. In an embodiment, the first semiconductor layer and the second semiconductor layer comprise germanium. In an embodiment, the second semiconductor layer has a greater germanium atomic percentage than the first semiconductor layer. In an embodiment, the lower source/drain region is formed at a first temperature, and the first epitaxy process is performed at a second temperature lower than the first temperature.

In an embodiment, the method further comprises forming an additional silicide layer on the lower source/drain region, wherein the silicide layer and the additional silicide layer are on opposing sides of the lower source/drain region; and forming a contact plug contacting the additional silicide layer, wherein the contact plug penetrates through the upper source/drain region. In an embodiment, the method further comprises forming a contact opening from a backside of the lower source/drain region, wherein the first semiconductor layer is formed in the contact opening.

In accordance with some embodiments of the present disclosure, a method comprises forming a first transistor comprising a first source/drain region, wherein the first source/drain region is over a semiconductor substrate; performing a backside thinning process to thin the semiconductor substrate; forming a contact opening from a backside of the semiconductor substrate, wherein a back surface of the first source/drain region is exposed; depositing a first semiconductor layer over the back surface of the first source/drain region; depositing a second semiconductor layer over the first semiconductor layer; siliciding the second semiconductor layer to form a silicide layer; and forming a backside contact plug joining to the silicide layer. In an embodiment, both of the first source/drain region and the first semiconductor layer comprise silicon germanium.

In an embodiment, the first semiconductor layer has a greater germanium atomic percentage than the first source/drain region. In an embodiment, the second semiconductor layer comprises germanium and is substantially free from silicon. In an embodiment, the first source/drain region is formed at a first temperature, and the first semiconductor layer and the second semiconductor layer are formed at a second temperature lower than the first temperature.

In an embodiment, the first semiconductor layer and the second semiconductor layer are deposited through selective epitaxy. In an embodiment, the method further comprises forming a second transistor comprising a second source/drain region, wherein the second source/drain region overlaps the first source/drain region. In an embodiment, the first transistor and the second transistor collectively form a complementary field-effect transistor.

In accordance with some embodiments of the present disclosure, a structure comprises a lower transistor comprising a lower source/drain region, wherein the lower source/drain region comprises a semiconductor region; and a first semiconductor layer underlying the semiconductor region; a first silicide layer underlying and electrically connected to the semiconductor region through the first semiconductor layer; a contact etch stop layer comprising a bottom part underlying the semiconductor region; and a sidewall portion contacting a sidewall of the semiconductor region, wherein the first semiconductor layer is lower than the sidewall portion of the contact etch stop layer; and a first contact plug underlying and joined to the first silicide layer.

In an embodiment, the structure further comprises a second semiconductor layer between the first semiconductor layer and the first silicide layer. In an embodiment, the structure further comprises a second silicide layer over and contacting the semiconductor region; and a second contact plug overlying and joined to the second silicide layer. In an embodiment, the structure further comprises an upper transistor comprising an upper source/drain region overlapping the lower source/drain region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a gate stack over a semiconductor region;
forming a dummy source/drain region on a side of the semiconductor region;
removing the dummy source/drain region to reveal the semiconductor region;
performing an epitaxy process to form a first replacement source/drain region on the semiconductor region;
forming a silicide layer on the first replacement source/drain region; and
forming a contact plug joined to the silicide layer.

2. The method of claim 1 further comprising:
forming an inter-layer dielectric over the dummy source/drain region; and
at a time after the gate stack is formed and before the dummy source/drain region is removed, removing the inter-layer dielectric.

3. The method of claim 1 further comprising forming an additional semiconductor region overlapping the semiconductor region, wherein the epitaxy process further results in a second replacement source/drain region to be grown from the additional semiconductor region.

4. The method of claim 3, wherein the first replacement source/drain region is separated from the second replacement source/drain region by a portion of the contact plug.

5. The method of claim 1, wherein the contact plug has a void therein.

6. The method of claim 1, wherein the dummy source/drain region comprises crystalline silicon.

7. The method of claim 1, wherein the dummy source/drain region comprises polysilicon.

8. The method of claim 1, wherein the dummy source/drain region comprises amorphous silicon.

9. The method of claim 1, wherein the dummy source/drain region is removed by processes comprising:
an anisotropic etching process to remove a part of the dummy source/drain region; and
an isotropic etching process to remove remaining portions of the dummy source/drain region.

10. A method comprising:
forming a first plurality of semiconductor nanostructures;
forming a second plurality of semiconductor nanostructures overlapping the first plurality of semiconductor nanostructures;
forming a lower dummy source/drain region contacting the first plurality of semiconductor nanostructures;
forming a first contact etch stop layer and a first inter-layer dielectric over the lower dummy source/drain region;
forming an upper dummy source/drain region contacting the second plurality of semiconductor nanostructures;
forming a second contact etch stop layer and a second inter-layer dielectric over the upper dummy source/drain region;
removing the second inter-layer dielectric, the second contact etch stop layer, and the upper dummy source/drain region to reveal the second plurality of semiconductor nanostructures; and
epitaxially growing an upper epitaxy semiconductor region on the second plurality of semiconductor nanostructures.

11. The method of claim 10, wherein the upper epitaxy semiconductor region comprises a plurality of portions separated from each other and formed starting from the second plurality of semiconductor nanostructures.

12. The method of claim 11 further comprising forming an upper contact plug electrically connected to the plurality of portions of the upper epitaxy semiconductor region.

13. The method of claim 12, wherein the plurality of portions of the upper epitaxy semiconductor region are separated from each other by the upper contact plug.

14. The method of claim 10 further comprising:
revealing the lower dummy source/drain region from an opposite side of the upper dummy source/drain region;
removing the lower dummy source/drain region; and
epitaxially growing a lower epitaxy semiconductor region on the first plurality of semiconductor nanostructures.

15. The method of claim 14, wherein the first contact etch stop layer and the first inter-layer dielectric are between the upper epitaxy semiconductor region and the lower epitaxy semiconductor region.

16. The method of claim 10, wherein the upper epitaxy semiconductor region is grown at a temperature lower than a temperature for forming the upper dummy source/drain region.

17. A method comprising:
forming a plurality of semiconductor nanostructures, with upper ones of the plurality of semiconductor nanostructures overlapping respective lower ones of the plurality of semiconductor nanostructures;
forming a dummy source/drain region contacting sidewalls of the plurality of semiconductor nanostructures;
forming a contact etch stop layer over the dummy source/drain region;
forming an inter-layer dielectric over the contact etch stop layer;
forming a gate stack over the plurality of semiconductor nanostructures;
removing the inter-layer dielectric, the contact etch stop layer, and the dummy source/drain region to reveal the sidewalls of the plurality of semiconductor nanostructures;
performing an epitaxy process to grow a plurality of semiconductor regions contacting the sidewalls of the plurality of semiconductor nanostructures; and
forming a plurality of silicide layers on the plurality of semiconductor regions.

18. The method of claim 17 further comprising forming a contact plug joined to the plurality of silicide layers.

19. The method of claim 17, wherein the dummy source/drain region is formed at a first wafer temperature, and the epitaxy process is performed at a second wafer temperature lower than the first wafer temperature.

20. The method of claim 17, wherein the dummy source/drain region has an amorphous structure.
